(19) United States
(12) Patent Application Publication
(10) Pub. No.: US 2022/0328320 A1
(43) Pub. Date: Oct. 13, 2022

(54) SEMICONDUCTOR TREATMENT LIQUID

(71) Applicant: TOKUYAMA CORPORATION, Yamaguchi (JP)

(72) Inventors: Yuki KIKKAWA, Yamaguchi (JP); Tomoaki SATO, Yamaguchi (JP); Takayuki NEGISHI, Yamaguchi (JP)

(73) Assignee: TOKUYAMA CORPORATION, Yamaguchi (JP)

(21) Appl. No.: 17/708,596

(22) Filed: Mar. 30, 2022

(30) Foreign Application Priority Data
Mar. 31, 2021 (JP) 2021-059498

(51) Int. Cl. H01L 21/306

(52) U.S. Cl. CPC H01L 21/30604

(57) ABSTRACT

Provided are: a semiconductor treatment liquid containing a hypobromite ion, in which the concentration of the hypobromite ion is 0.1 μmol/L or more and less than 0.001 mol/L; a RuO₄ gas generation inhibitor containing an onium salt composed of an onium ion and a bromine-containing ion, in which the hypobromite ion concentration is 0.1 μmol/L or more and less than 0.001 mol/L; and a method of producing a halogen oxyacid, the method including allowing a bromine salt, an organic alkali, and a halogen to react with each other to obtain the halogen oxyacid.

### BACKGROUND OF THE INVENTION

### Field of the Invention

The present invention relates to a semiconductor treatment liquid containing a hypobromite ion (hereinafter, also simply referred to as “treatment liquid”), in which the concentration of the hypobromite ion is 0.1 μmol/L or more and less than 0.001 mol/L. The present invention also relates to a RuO₄ gas generation inhibitor containing an onium salt composed of an onium ion and a bromine-containing ion, in which the concentration of a hypobromite ion is 0.1 μmol/L or more and less than 0.001 mol/L. Further, the present invention relates to a method of producing a halogen oxyacid.

### BACKGROUND ART

In recent years, the design rules for semiconductor elements have been refined, and the wiring resistance tends to be increased. As a result of the increase in the wiring resistance, the high-speed operations of semiconductor elements have been markedly impaired, making it necessary to take countermeasures. In light of this, a wiring material having a higher electromigration resistance and a lower resistance value than conventional wiring materials is desired.

As compared to aluminum and copper which are conventional wiring materials, ruthenium, tungsten, molybdenum, and chromium have a higher electromigration resistance and can reduce the resistance value of a wiring. For this reason, ruthenium, tungsten, molybdenum, and chromium have been attracting attention particularly as wiring materials that allow a design rule of 10 nm or less in a semiconductor element. In addition, since ruthenium can prevent electromigration even when copper is used in a wiring material, the use of ruthenium has been examined not only as a wiring material but also as a barrier metal for copper wiring.

Incidentally, even when ruthenium, tungsten, molybdenum, or chromium is selected as a wiring material in the step of forming a wiring of a semiconductor element, a wiring can be formed by dry etching or wet etching in the same manner as in the case of using a conventional wiring material. However, for ruthenium, tungsten, molybdenum, and chromium, since etching in a dry state using an etching gas and etching/removal by CMP polishing are difficult, a more precise etching method is desired and, specifically, wet etching has been attracting attention.

In wet etching of ruthenium, tungsten, molybdenum or chromium, the dissolution rate of the metal, namely the etching rate, is important. When the etching rate is high, the metal can be dissolved in a short time, so that the number of wafers treated per unit time can be increased.

Further, in a case where ruthenium, tungsten, molybdenum, or chromium is used as a wiring material, the stability of the etching rate is particularly important. When the etching rate is stable, the accuracy of processing the metal can be improved by controlling the etching time. Especially, for ultrafine wiring, precise processing of ruthenium, tungsten, molybdenum, or chromium is indispensable. Therefore, an etching liquid that has an excellent etching rate stability and can maintain the flatness of a transition metal surface is desired, particularly for the step of forming a fine wiring using ruthenium, tungsten, or molybdenum.

Meanwhile, for the purpose of etching ruthenium that is a noble metal and not easily dissolved or etching tungsten, molybdenum or chromium at a high rate, a highly oxidative oxidizing agent may be incorporated into an etching liquid. In such a case, in order to improve the production efficiency and maintain the processing accuracy, the etching liquid is demanded to have a sufficient etching rate with excellent stability and be able to maintain the flatness of a metal surface after etching.

When ruthenium is wet-etched in an alkaline condition, ruthenium is dissolved in the form of, for example, RuO₄⁻ and RuO₄²⁻, in a treatment liquid. RuO₄⁻ and RuO₄²⁻ are converted into RuO₄ in the treatment liquid, and a portion thereof is gasified and released into a gas phase. RuO₄ is not only strongly oxidative and thus harmful to the human body, but also easily reduced to form RuO₂ particles. Generally, such particles cause a reduction in the yield, and this presents a major problem in a semiconductor fabrication process. In view of this background, it is extremely important to inhibit the generation of RuO₄ gas.

As a treatment liquid used for etching ruthenium from a semiconductor wafer, Patent Document 1 proposes a treatment liquid for ruthenium-containing wafers, which contains a hypochlorite ion and a solvent and has a pH of higher than 7 and lower than 12.0 at 25° C. It is shown that this treatment liquid contains a hypochlorite ion and is capable of removing ruthenium and tungsten adhering to an end face portion and a back surface portion of a semiconductor wafer. In addition, as a method of producing the hypochlorite ion-containing treatment liquid, Patent Document 1 discloses a method that uses an ion exchange resin.

Patent Document 2 discloses an etching composition for ruthenium-based metals, which is obtained by adding and mixing a bromine-containing compound, an oxidizing agent, a basic compound and water. This etching composition is characterized in that the bromine-containing compound is added in an amount of 2 to 25% by mass in terms of bromine element and the oxidizing agent is added in an amount of 0.1 to 12% by mass, with respect to a total mass of the composition, and that the pH is 10 or higher and lower than 12.

Patent Document 3 proposes an etching liquid for tungsten and titanium-tungsten alloys, which contains hydrogen peroxide and an alkali component, and has a pH of 7 or lower. It is shown that this etching liquid is capable of stably etching tungsten used as an electrode or wiring of a thin-film transistor, or a barrier metal of the electrode or wiring, in semiconductor devices and liquid crystal display devices.

Patent Document 4 discloses a method of forming a wiring by processing copper, molybdenum and the like with a chemical solution containing an oxidizing agent and an acid. As the oxidizing agent, hydrogen peroxide, persulfuric acid, nitric acid, hypochlorous acid, permanganic acid, and dichromic acid are mentioned as examples. In addition, Patent Document 4 shows an example where a molybdenum film was etched using, as the chemical solution, an aqueous solution containing hydrogen peroxide and a carboxylic acid.

### RELATED ART DOCUMENTS

### Patent Documents

[Patent Document 1] WO2019/142788
[Patent Document 2] WO2011/074601
[Patent Document 3] Japanese Unexamined Patent Application Publication No. 2004-031791
[Patent Document 4] Japanese Unexamined Patent Application Publication No. 2013-254946

### SUMMARY OF THE INVENTION

### Problems to be Solved by the Invention

For etching of a transition metal or the like on a semiconductor wafer using a treatment liquid, it is important that the treatment liquid should have both sufficient etching rate and satisfactory etching rate stability and be able to maintain the surface flatness after etching. In addition, in the case of wet etching ruthenium in an alkaline condition, it is important to inhibit the generation of RuO₄ gas. Further, it is also important to produce a halogen oxyacid with a good yield in a simple manner. However, according to the studies conducted by the present inventors, it was found that those conventional treatment liquids and compositions disclosed in prior art documents have room for improvement in terms of the following aspects.

For example, as a treatment liquid for ruthenium-containing wafers, Patent Document 1 discloses a treatment liquid having a pH of higher than 7 and lower than 12.0. This treatment liquid disclosed in Patent Document 1 has a sufficient ruthenium etching rate; however, the stability of the etching rate tends to be deteriorated when the treatment liquid contains an oxidizing agent at a high concentration. Thus, it is difficult to achieve both sufficient etching rate and satisfactory etching rate stability at the same time by using the treatment liquid for ruthenium-containing wafers disclosed in Patent Document 1. It is also difficult to maintain the flatness of a ruthenium surface after etching.

The etching composition disclosed in Patent Document 2 is capable of etching ruthenium at a sufficient rate. As a method of preparing this etching composition, Patent Document 2 describes a method in which an oxide obtained by oxidizing a bromine-containing compound with an oxidizing agent in an acidic condition is mixed with a basic compound to appropriately adjust the pH to be basic. However, as a result of additional tests conducted by the present inventors, this etching composition was revealed to have problems in that it has poor chemical solution stability, and that its ruthenium etching rate largely varies with time. Thus, it is difficult to achieve both sufficient etching rate and satisfactory etching rate stability at the same time by using the etching composition disclosed in Patent Document 2. In addition, there is a problem in that the etching composition has a difficultly in maintaining the flatness of a ruthenium surface after etching and rather causes an increase in the roughness of the metal surface.

The etching liquid disclosed in Patent Document 3 contains hydrogen peroxide as a main component and thus has problems in that its etching rate is not stable due to self-decomposition reaction of hydrogen peroxide, and that the etching liquid has a short life. In addition, the etching rate is not necessarily said to be sufficient. Accordingly, it is difficult to achieve both sufficient etching rate and satisfactory etching rate stability at the same time by using the etching liquid disclosed in Patent Document 3. Further, there is a problem in that the etching liquid has a difficultly in maintaining the flatness of a tungsten surface after etching and rather causes an increase in the roughness of the metal surface.

The chemical solution disclosed in Patent Document 4 contains an oxidizing agent and an acid. Hydrogen peroxide is the only oxidizing agent disclosed in Examples of Patent Document 4, and this chemical solution has problems in that, as described above, its etching rate is not stable due to self-decomposition reaction of hydrogen peroxide, and that the chemical solution has a short life. In addition, the etching rate is not necessarily said to be sufficient. Accordingly, it is difficult to achieve both sufficient etching rate and satisfactory etching rate stability at the same time by using the chemical solution disclosed in Patent Document 4. Further, there is a problem in that the chemical solution has a difficultly in maintaining the flatness of a molybdenum surface after etching and rather causes an increase in the roughness of the metal surface.

Moreover, the above-described Patent Documents 1 to 4 do not mention at all with regard to the inhibition of RuO₄ gas generation and, actually, the generation of RuO₄ gas cannot be inhibited by the treatment liquids and compositions that are disclosed in Patent Documents 1 to 4. Besides, there is no method for producing the above-described halogen oxyacid with a good yield in a simple manner.

Therefore, the present invention was made in view of the above-described background art, and an object of the present invention is to provide a semiconductor treatment liquid which has a sufficient etching rate and an excellent stability of the etching rate, and with which etching can be stably performed over an extended period even at normal temperature and the flatness of a metal surface can be maintained after the etching. Another object of the present invention is to provide a RuO₄ gas generation inhibitor which can inhibit the generation of RuO₄ gas during etching of ruthenium. Yet another object of the present invention is to provide a method of producing a halogen oxyacid with a good yield in a simple manner.

### Means for Solving the Problems

The present inventors intensively studied to solve the above-described problems.

As a result, the present inventors discovered that, by treating a semiconductor wafer with a treatment liquid having a hypobromite ion concentration of 0.1 μmol/L or more and less than 0.001 mol/L, a transition metal can be stably etched at a sufficient rate even at normal temperature, and the flatness of the metal surface can be maintained after the etching. The present inventors also discovered that, in etching of ruthenium, the generation of RuO₄ gas can be inhibited by using a RuO₄ gas generation inhibitor having a bromine-containing ion concentration of 0.1 μmol/L or more and less than 0.001 mol/L. Further, the present inventors discovered a method of producing a halogen oxyacid with a good yield in a simple manner, thereby completing the present invention.

That is, the present invention encompasses the following constitutions.

[1] A semiconductor treatment liquid, containing a hypobromite ion,

wherein the concentration of the hypobromite ion is 0.1 μmol/L or more and less than 0.001 mol/L.

[2] The semiconductor treatment liquid according to [1], wherein the semiconductor contains a transition metal.

[3] The semiconductor treatment liquid according to [1] or [2], further containing at least one anion species selected from the group consisting of a chlorate ion, a chlorite ion, a chloride ion, a bromate ion, a bromite ion, and a bromide ion.

[4] The semiconductor treatment liquid according to any one of [1] to [3], wherein

the semiconductor treatment liquid further contains an oxidizing agent, and

the oxidizing agent has a redox potential higher than that of a hypobromite ion/bromide ion system.

[5] The semiconductor treatment liquid according to [4], wherein the oxidizing agent is at least one oxidizing agent selected from the group consisting of a hypochlorite ion, ozone, an orthoperiodate ion, and a metaperiodate ion.

[6] The semiconductor treatment liquid according to any one of [1] to [5], further containing a tetraalkylammonium ion.

[7] The semiconductor treatment liquid according to any one of [1] to [6], having a pH of 8 or higher and 14 or lower.

[8] A RuO₄ gas generation inhibitor, containing an onium salt composed of an onium ion and a bromine-containing ion,

wherein the concentration of the bromine-containing ion in the RuO₄ gas generation inhibitor is 0.1 μmol/L or more and less than 0.001 mol/L.

[9] The RuO₄ gas generation inhibitor according to [8], wherein the onium salt is a quaternary onium salt represented by the following Formula (1), or a tertiary onium salt represented by the following Formula (2):

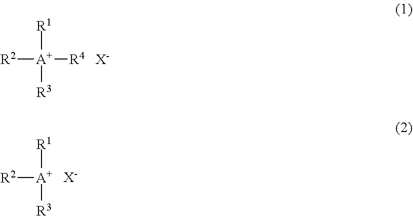

(in Formula (1), A represents nitrogen or phosphorus; R¹, R², R³, and R⁴ each independently represent an alkyl group having carbon number of 1 to 25, an allyl group, an aralkyl group containing an alkyl group having carbon number of 1 to 25, or an aryl group, provided that when R¹, R², R³, and R⁴ are alkyl groups, at least one of the alkyl groups of R¹, R², R³, and R⁴ has carbon number of 3 or more; and, in a ring of an aryl group in the aralkyl group and in a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom,

in Formula (2), A represents sulfur; R¹, R², and R³ each independently represent an alkyl group having carbon number of 1 to 25, an allyl group, an aralkyl group containing an alkyl group having carbon number of 1 to 25, or an aryl group, provided that when R¹, R², and R³ are alkyl groups, at least one of the alkyl groups of R¹, R², and R³ has carbon number of 3 or more; and, in a ring of an aryl group in the aralkyl group and in a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom, and

X⁻ represents a bromine-containing ion).

[10] The RuO₄ gas generation inhibitor according to [9], wherein the quaternary onium salt is a tetraalkylammonium salt.

[11] The RuO₄ gas generation inhibitor according to any one of [8] to [10], wherein the bromine-containing ion is a bromite ion, a bromate ion, a perbromate ion, a hypobromite ion, or a bromide ion.

[12] The RuO₄ gas generation inhibitor according to any one of [8] to [11], further containing an oxidizing agent.

[13] The RuO₄ gas generation inhibitor according to [12], wherein

the oxidizing agent is a hypochlorite ion, and

the concentration of the hypochlorite ion is 500 ppb by mass to 20.0% by mass.

[14] A method of producing a halogen oxyacid, the method including allowing a bromine salt, an organic alkali, and a halogen to react with each other to obtain the halogen oxyacid.

[15] The method of producing a halogen oxyacid according to [14], wherein the organic alkali is an onium hydroxide.

[16] The method of producing a halogen oxyacid according to [14] or [15], wherein the halogen is chlorine.

[17] The method of producing a halogen oxyacid according to any one of [14] to [16], wherein the concentration of the halogen oxyacid is 0.1 μmol/L or more and less than 0.001 mol/L.

### Effects of the Invention

According to the semiconductor treatment liquid of the present invention, a transition metal can be stably wet-etched at a sufficient rate in a semiconductor formation process. In addition, the roughness of the transition metal surface after etching can be reduced, and the flatness can be maintained. By all of these effects, not only the accuracy of processing a transition metal contained in a semiconductor wafer and the yield are improved, but also the wafer processing efficiency per unit time is improved. Further, according to the RuO₄ gas generation inhibitor of the present invention, the generation of RuO₄ gas during etching of ruthenium can be inhibited. Moreover, according to the production method of the present invention, a halogen oxyacid can be produced with a good yield in a simple manner. According to this production method, the amount of metals contained in the resulting halogen oxyacid can be reduced.

### BRIEF DESCRIPTION OF THE DRAWING

FIG. 1 is a schematic drawing that illustrates one mode of the RuO₄ gas measurement method according to one embodiment of the present invention.

### MODE FOR CARRYING OUT THE INVENTION

### (Semiconductor Treatment Liquid)

The semiconductor treatment liquid according to a first embodiment of the present invention (hereinafter, also simply referred to as “treatment liquid”) is a semiconductor wafer treatment liquid characterized by containing 0.1 μmol/L or more and less than 0.001 mol/L of hypobromite ion (BrO⁻). A hypobromite ion is a strongly oxidative oxidizing agent, and the treatment liquid of the present embodiment which contains 0.1 μmol/L or more and less than 0.001 mol/L of hypobromite ion is capable of stably etching, for example, a transition metal at a sufficient rate under an alkaline condition, and maintaining the flatness of the metal surface after the etching. In addition, by appropriately selecting the pH of the treatment liquid as well as the type and the concentration of the oxidizing agent, a transition metal can be etched with the treatment liquid at a stable etching rate while inhibiting the generation of RuO₄ gas. Further, the treatment liquid can also be used for, for example, removing a hardly soluble resist, or removing residues after dry etching of a resist. Therefore, the treatment liquid of the present embodiment can be preferably used in the etching step, the residue removal step, the washing step, the CMP step and the like in a semiconductor fabrication process. In the present embodiment, the term “hypohalous acid” refers to hypobromous acid, hypochlorous acid, or hypoiodous acid, and the term “hypohalite ion” refers to a hypobromite ion, a hypochlorite ion, or a hypoiodite ion.

In the present embodiment, examples of the transition metal include at least one metal selected from Ru, Rh, Ti, Ta, Co, Cr, Hf, Os, Pt, Ni, Mn, Cu, Zr, La, Mo, and W. Cases where the transition metal is ruthenium, tungsten, molybdenum, or chromium will now be described as examples. By using the treatment liquid of the present embodiment, ruthenium, tungsten, molybdenum, or chromium adhering to the surface, an edge portion, and a back surface portion of a semiconductor wafer can be removed at a sufficient etching rate in a stable manner while maintaining the surface flatness. The term “sufficient etching rate” used herein refers to an etching rate of 10 Å/min or higher when the transition metal to be etched is ruthenium, or an etching rate of 50 Å/min or higher when the transition metal to be etched is tungsten, molybdenum, or chromium. As long as the etching rate of ruthenium, tungsten, molybdenum, or chromium satisfies the above-described value, the treatment liquid of the present embodiment can be preferably used in the etching step, the residue removal step, the washing step, the CMP step, and the like.

A transition metal included in a semiconductor wafer to which the treatment liquid of the present embodiment is applied can be formed by any method. For the formation of a transition metal film, a method widely known in semiconductor fabrication process, such as CVD, ALD, sputtering, or plating, can be utilized. The semiconductor wafer to which the treatment liquid of the present embodiment is applied can contain one transition metal, or plural transition metals. It is noted here that the term “transition metal semiconductor” used herein means a transition metal-containing semiconductor.

In the present embodiment, “ruthenium” is not limited to metal ruthenium as long as it contains elemental ruthenium, and examples thereof include Ru, RuO₄⁻, RuO₄²⁻, RuO₄, RuO₂, RuO₃, a ruthenium complex, and a ruthenium alloy.

In the present embodiment, “tungsten” encompasses not only metal tungsten, a tungsten-based metal containing tungsten as a main component, and an alloy of tungsten and other metal, but also a compound substantially containing tungsten. Examples of the tungsten-based metal include tungsten oxides (W_{X}O_{Y}), tungsten nitride (WN), tungsten oxynitride (WNO) and cobalt tungsten phosphor (CoWP), and the tungsten oxides are, for example, tungsten dioxide (WO₂), tungsten trioxide (WO₃), and ditungsten pentoxide (W₂O₅). The tungsten oxides (W_{X}O_{Y}) also include those cases where x and y are not integers. i.e. nonstoichiometric tungsten oxides.

In the present embodiment, “molybdenum” encompasses not only metal molybdenum, a molybdenum-based metal containing molybdenum as a main component, and an alloy of molybdenum and other metal, but also a compound substantially containing molybdenum. Examples of the molybdenum-based metal include molybdenum oxides (Mo_{X}O_{Y}), molybdenum nitride (MoN) and molybdenum oxynitride (MoNO), and the molybdenum oxides are, for example, molybdenum dioxide (MoO₂), molybdenum trioxide (MoO₃), and dimolybdenum pentoxide (Mo₂O₅). The molybdenum oxides (Mo_{X}O_{Y}) also include those cases where x and y are not integers. i.e. nonstoichiometric molybdenum oxides.

In the present embodiment, “chromium” encompasses not only metal chromium, a chromium-based metal containing chromium as a main component, and an alloy of chromium and other metal, but also a compound substantially containing chromium. Examples of the chromium-based metal include chromium oxides (Cr_{X}O_{Y}), chromium nitride (CrN) and chromium oxynitride (CrNO), and the chromium oxides are, for example, chromium dioxide (CrO₂), chromium trioxide (CrO₃), and dichromium pentoxide (Cr₂O₅). The chromium oxides (Cr_{X}O_{Y}) also include those cases where x and y are not integers, i.e. nonstoichiometric chromium oxides.

An alloy of a transition metal and other metal can contain any metal besides the transition metal. Examples of a metal other than a transition metal that is contained in an alloy of the transition metal and other metal include tantalum, silicon, copper, hafnium, zirconium, aluminum, vanadium, cobalt, nickel, manganese, gold, rhodium, palladium, titanium, ruthenium, molybdenum, tungsten, and chromium, and the alloy can also contain an oxide, nitride, carbide, or silicide of any of the above-described metals.

These transition metals can also be in the form of an intermetallic compound, an ionic compound, or a complex. Further, the transition metals can be exposed on the wafer surface, or covered by other metal, a metal oxide film, an insulating film, a resist, or the like.

The treatment liquid of the present embodiment is capable of etching ruthenium, tungsten, molybdenum, or chromium; however, it does not etch metals such as copper, cobalt, titanium, platinum, titanium nitride, and tantalum nitride, or etches these metals at a much lower rate than ruthenium, tungsten, molybdenum, or chromium. Accordingly, in a semiconductor fabrication process and the like, the treatment liquid is also capable of selectively etching ruthenium, tungsten, molybdenum, or chromium without damaging a substrate material containing the above-described metals.

In the present embodiment, a “stable etching rate” means that the rate of etching performed by a hypobromite ion-containing treatment liquid does not change with time. Specifically, a “stable etching rate” means that, when plural wafers containing a transition metal (the number of the wafers is defined as “n”) are etched using the same treatment liquid, the etching rate of the transition metal on the first wafer is substantially the same as the etching rate of the transition metal on the n^{th} wafer. The term “substantially the same” used herein means that a range of variation in the etching rate of the transition metal on the n^{th} wafer with respect to the etching rate of the transition metal on the first wafer, i.e. an increase or decrease in the etching rate, is within ±20%. Further, a period in which an increase or decrease in the etching rate of the transition metal on the n^{th} wafer with respect to the etching rate of the transition metal on the first wafer is within ±20% is defined as “etching rate stability time”. A preferred value of the etching rate stability time varies depending on the use conditions and production process of the treatment liquid of the present embodiment; however, for example, a treatment liquid having an etching rate stability time of 1 hour or longer can be preferably used in a semiconductor fabrication process. In consideration of providing a sufficient time for handling of the treatment liquid and enabling to set the process time in a flexible manner, the etching rate stability time of the treatment liquid is more preferably 10 hours or longer.

A treatment liquid whose etching rate of a transition metal does not vary with time, or a treatment liquid having a long etching rate stability time makes it possible not only to stably perform etching of a transition metal using the treatment liquid in a semiconductor fabrication process, but also to recycle (reuse) the treatment liquid; therefore, such a treatment liquid is also excellent in terms of productivity and cost.

Further, the treatment liquid of the present embodiment is a treatment liquid that can maintain the flatness of a transition metal surface after etching. In the present embodiment, an expression “the flatness of a transition metal surface is maintained after etching” means that the flatness of a transition metal surface subjected to etching does not substantially change before and after the etching or, even if a change occurs in the flatness, it is within a range that does not cause a practical problem. Cases where the flatness of a transition metal surface is not maintained include, for example, not only a case where etching causes pitting corrosion on a transition metal film and a case where etching is not uniform (positional variation), but also a case where the roughness of the metal surface (surface roughness) is increased. The flatness of a transition metal surface can be easily checked by, for example, observation of the transition metal surface under a scanning electron microscope (SEM), or observation/measurement of the transition metal surface under an atomic force microscope (AFM). Therefore, with regard to a wafer containing a transition metal to be etched, the surface thereof is observed/measured by the above-described evaluation method before and after an etching treatment and the results thereof are compared, whereby whether or not the flatness of the metal surface is maintained after the etching treatment can be easily judged.

By maintaining the flatness of a transition metal surface after etching, the adhesion of other semiconductor material, such as an interlayer insulating film or other metal material, that is brought into contact with the transition metal surface after etching is improved; therefore, not only the performance and the reliability but also the yield of a fine wiring and a semiconductor element to be formed are improved. The flatness of the transition metal surface after etching becomes more important when the fineness of the wiring and the element increases, and the use of the treatment liquid of the present embodiment enables to stably etch a transition metal contained in a wafer at a sufficient rate and to maintain the flatness of the transition metal surface after the etching. The treatment liquid of the present embodiment can be particularly preferably used when, for example, a wiring used for semiconductor fabrication has a width of 10 nm or less.

### (Hypobromite Ion)

The hypobromite ion contained in the treatment liquid of the present embodiment can be generated in the treatment liquid, or can be added to the treatment liquid as a hypobromite. The term “hypobromite” used herein refers to a salt containing a hypobromite ion, or a solution containing such a salt. In order to generate the hypobromite ion in the treatment liquid, for example, bromine gas can be blown into the treatment liquid. In this case, from the standpoint of generating the hypobromite ion efficiently, the temperature of the treatment liquid is preferably 50° C. or lower. When the temperature of the treatment liquid is 50° C. or lower, not only the hypobromite ion can be generated efficiently, but also the generated hypobromite ion can be used for etching a transition metal in a stable manner. Further, in order to dissolve a larger amount of bromine in the treatment liquid, the temperature of the treatment liquid is more preferably 30° C. or lower, most preferably 25° C. or lower. A lower limit of the temperature of the treatment liquid is not particularly limited; however, the treatment liquid is preferably not frozen. Accordingly, the temperature of the treatment liquid is preferably −35° C. or higher, more preferably −15° C. or higher, most preferably 0° C. or higher. The pH of the treatment liquid into which bromine gas is blown is not particularly limited; however, as long as the pH is in the alkaline range, the treatment liquid can be used for etching a transition metal immediately after the generation of hypobromite ion.

In the case of blowing bromine gas into the treatment liquid to generate the hypobromite ion, the solubility of bromine gas (Br₂) is improved when the treatment liquid contains a bromide ion (Br⁻). This is because Br₂ dissolved in the treatment liquid reacts with Br⁻ and Br₃⁻ to form complex ions such as Br₃⁻ and Br₅⁻ and are thereby stabilized in the treatment liquid. A treatment liquid containing a large amount of Br₂, Br⁻, Br₃⁻, Br₅⁻ and the like can generate a greater amount of hypobromite ion and, therefore, can be suitably used as the treatment liquid of the present embodiment.

Alternatively, the hypobromite ion can be generated in the treatment liquid by oxidizing a bromine-containing compound with an oxidizing agent.

In order to add the hypobromite ion as a compound to the treatment liquid, hypobromous acid, bromine water, and/or a hypobromite can be added to the treatment liquid. The hypobromite is preferably sodium hypobromite, potassium hypobromite, or a tetraalkylammonium hypobromite and, from the standpoint of not containing any metal ion that causes a problem in semiconductor fabrication, the hypobromite is more preferably hypobromous acid or a tetraalkylammonium hypobromite.

The tetraalkylammonium hypobromite can be easily obtained by passing bromine gas through a tetraalkylammonium hydroxide solution. Alternatively, the tetraalkylammonium hypobromite can be obtained by mixing hypobromous acid and a tetraalkylammonium hydroxide solution. Further, the tetraalkylammonium hypobromite can also be obtained by substituting a cation contained in a hypobromite, such as sodium hypobromite, with a tetraalkylammonium ion using an ion exchange resin.

In the treatment liquid of the present embodiment, the concentration of the hypobromite ion is 0.1 μmol/L or more and less than 0.001 mol/L. When the concentration of the hypobromite ion is less than 0.1 μmol/L, the etching rate of a transition metal is low, and the treatment liquid thus has a low practicality. Meanwhile, when the concentration of the hypobromite ion is 0.001 mol/L or more, for example, decomposition of the hypobromite ion is likely to occur at a high temperature or the like, and this makes the etching rate of a transition metal unlikely to be stable. Further, a concentration of 0.001 mol/L or more tends to make it difficult to maintain the flatness of a transition metal surface after etching. In order to stably perform etching of a transition metal at a sufficient rate and to maintain the flatness of the metal surface after the etching, the concentration of the hypobromite ion is 0.1 μmol/L or more and less than 0.001 mol/L, preferably 1 μmol/L or more and less than 0.001 mol/L, more preferably 10 μmol/L or more and less than 0.001 mol/L, still more preferably 50 μmol/L or more and less than 0.001 mol/L, most preferably 50 μmol/L or more and less than 0.0005 mol/L.

The concentration of the hypobromite ion in the treatment liquid can be determined by calculation based on the production conditions, or using a widely known method. For example, UV-visible absorptiometry can be employed to easily check absorption attributed to the hypobromite ion, and the hypobromite ion concentration can be determined from the intensity of an absorption peak (which is generally observed at about 330 nm, although this depends on the pH, the hypobromite ion concentration and the like of the treatment liquid). The hypobromite ion concentration can be determined by iodine titration as well. Further, the hypobromite ion concentration can also be determined from the redox potential (ORP) or the pH of the treatment liquid. Measurement by UV-visible absorptiometry is most preferred since the measurement can be carried out in a contact-less and continuous manner. In the measurement of the hypobromite ion concentration by UV-visible absorptiometry, when other chemical species exhibits absorption, the hypobromite ion concentration can be determined with sufficient accuracy by performing data processing such as spectral splitting and baseline correction, and selecting an appropriate reference.

The acid dissociation constant (pKₐ) of hypobromous acid (HBrO) and hypobromite ion (BrO⁻) is 8.6; therefore, HBrO and BrO⁻ may coexist depending on the pH of the treatment liquid, for example, when the pH is low. When the treatment liquid contains both HBrO and BrO⁻, a total concentration of HBrO and BrO⁻ can be taken as the above-described hypobromite ion concentration.

The details of the mechanism by which the hypobromite ion dissolves ruthenium are not necessarily clear; however, it is presumed that the hypobromite ion or hypobromous acid generated therefrom oxidizes ruthenium in the treatment liquid to form RuO₄, RuO₄⁻, or RuO₄²⁻ and thereby dissolves ruthenium in the treatment liquid. By dissolving ruthenium in the form of RuO₄⁻ or RuO₄²⁻, the amount of RuO₄ gas generation can be reduced, and the generation of RuO₂ particles can be inhibited. In order to dissolve ruthenium in the form of RuO₄⁻ or RuO₄²⁻, the pH of the treatment liquid is preferably in the alkaline range, more preferably 8 to 14, still more preferably 12 to 14, most preferably 12 or higher and lower than 13. When the pH of the treatment liquid is 12 or higher and lower than 13, ruthenium is dissolved in the form of RuO₄⁻ or RuO₄²⁻ in the treatment liquid, so that the amount of RuO₄ gas generation can be greatly reduced, and the generation of RuO₂ particles can be inhibited. Meanwhile, when the pH of the treatment liquid is lower than 8, ruthenium is likely to be oxidized to RuO₂ and RuO₄; therefore, the amount of RuO₂ particles and the amount of RuO₄ gas generation tend to be increased. Further, ruthenium is unlikely to be dissolved when the pH is higher than 14, and this makes it difficult to obtain a sufficient ruthenium etching rate, as a result of which the production efficiency in semiconductor fabrication is reduced. As long as the pH of the treatment liquid is 8 or higher and 14 or lower, the treatment liquid can not only stably etch ruthenium at a sufficient rate and maintain the flatness of the ruthenium surface after etching, but also reduce the amount of RuO₄ gas generation.

The details of the mechanism by which the hypobromite ion dissolves tungsten, molybdenum, or chromium are not necessarily clear, however, it is presumed that the hypobromite ion or hypobromous acid generated therefrom oxidizes tungsten, molybdenum, or chromium in the treatment liquid to form MO₄, MO₄⁻, or MO₄²⁻ (wherein, M represents tungsten (W), molybdenum (Mo), or chromium (Cr)) and thereby dissolves tungsten, molybdenum, or chromium in the treatment liquid. By dissolving tungsten, molybdenum, or chromium in the form of the above-described chemical species in the treatment liquid, precipitation of an oxide on the transition metal surface can be inhibited. Precipitation of an oxide on the transition metal surface cause a large change in the etching rate of the transition metal, and thus reduces the stability of the etching rate and deteriorates the flatness of the metal surface. Therefore, it is preferred that tungsten, molybdenum, or chromium be dissolved in the form of the above-described chemical species in the treatment liquid and, to achieve this, the pH of the treatment liquid is preferably in the alkaline range, more preferably 8 or higher and 14 or lower, still more preferably 12 or higher and 14 or lower, most preferably 12 or higher and lower than 13.

### (Anion Species)

The treatment liquid of the present embodiment can further contain at least one anion species selected from the group consisting of a chlorate ion, a chlorite ion, a chloride ion, a bromate ion, a bromite ion, and a bromide ion. It is presumed that the surface roughness is further reduced by interaction between these anion species and a metal. In other words, by incorporating these anion species into the treatment liquid of the present embodiment, the flatness of a transition metal surface after etching is likely to be maintained. The treatment liquid can contain any one of these anion species, or two or more of these anion species. Among these anion species, bromide ion is preferred because of its solubility in the treatment liquid, availability, cost, and the like. When two or more anions are contained in the treatment liquid, from the standpoint of effectively reducing the roughness of a metal surface, the anions particularly preferably include one selected from a chloride ion, a chlorate ion, a bromide ion, and a bromate ion.

The anion species used in the present embodiment can be generated by dissolving an acid, a salt or the like that contains the anion species into the treatment liquid. Examples of the acid containing the anion species include chloric acid, chlorous acid, hydrogen chloride, bromic acid, bromous acid, and hydrogen bromide. Further, examples of the salt containing the anion species include alkali metal salts, alkaline earth metal salts, and organic salts. Specifically, examples of the alkali metal salts include sodium chloride, sodium chlorate, sodium chlorite, potassium bromide, and sodium bromite, and examples of the organic salts include organic salts containing an onium ion of a quaternary alkylammonium salt, such as tetramethylammonium chloride and tetramethylammonium bromide. Hydrogen bromide can be generated by dissolving a halogen gas, such as bromine gas, into water. Among these acids and salts, an acid or organic salt that contains the anion species is preferably used since it does not contain any metal ion that causes a problem in semiconductor fabrication and, taking into consideration the industrial availability and the ease of handling, the anion species is more preferably an onium ion-containing organic salt such as a quaternary alkylammonium salt. Among such organic salts, from the standpoint of stability, purity and cost, for example, at least one selected from the group consisting of tetramethylammonium chloride, tetramethylammonium bromide, ethyltrimethylammonium chloride, tetraethylammonium bromide, tetraethylammonium chloride, tetraethylammonium bromide, tetrapropylammonium chloride, tetrapropylammonium bromide, tetramethylammonium chlorate, tetramethylammonium bromate, tetramethylammonium chlorite, and tetramethylammonium bromite can be particularly preferably used.

The content of the anion species in the treatment liquid is not particularly limited, and can be determined as appropriate taking into consideration, for example, the type and the stability of anion, the hypobromite ion concentration, the types and the amounts of the below-described other additives, and the etching conditions (e.g., treatment time and treatment temperature). Generally, the flatness of a metal surface tends to be deteriorated when the etching time is long and/or the etching amount is large. In such a case, the flatness of the metal surface after etching can be maintained by increasing the amount of the anion species contained in the treatment liquid of the present embodiment. The content of the anion species in the treatment liquid is, for example, 0.01 μmol/L or more and 10.0 mol/L or less, preferably 0.01 mmol/L or more and 7.00 mol/L or less, more preferably 1 mmol/L or more and 5.00 mol/L or less. The content of the anion species in the treatment liquid can be measured by ion chromatography method. In this measurement method, the anion species can be identified and quantified by appropriately setting the type and the conditions of a column.

(Oxidizing Agent Other than Hypobromite Ion)

In the treatment liquid of the present embodiment, the hypobromite ion functions as an oxidizing agent to etch a transition metal. The treatment liquid preferably farther contains an oxidizing agent different from the hypobromite ion. This oxidizing agent contained in the treatment liquid of the present embodiment plays a role of oxidizing a bromide ion (Br⁻), which is generated by decomposition of the hypobromite ion, back to the hypobromite ion.

When a transition metal is oxidized, a hypobromite ion is reduced to Br⁻. In addition, hypobromite ions are easily and naturally decomposed in the treatment liquid, and some of them are converted to Br⁻. Further, the decomposition of hypobromite ions is facilitated by UV light and visible light, and some of the hypobromite ions are converted to Br⁻. Moreover, the decomposition of hypobromite ions is also facilitated by heating, contact with an acid, and contact with a metal, and some of the hypobromite ions are converted to Br⁻. Br⁻ generated by reduction or decomposition of a hypobromite ion does not dissolve a transition metal; therefore, the etching rate of the transition metal decreases with the progress of reduction or decomposition of hypobromite ions. By incorporating an appropriate oxidizing agent into the treatment liquid, Br⁻ generated by such reduction or decomposition can be oxidized to a hypobromite ion, so that the decrease in the etching rate of a transition metal can be alleviated. In other words, by incorporating a hypobromite ion and an appropriate oxidizing agent into the treatment liquid, the etching rate stability time can be extended.

With regard to the oxidizing agent optionally contained in the treatment liquid, the redox potential between the oxidizing agent and a chemical species generated by reduction of the oxidizing agent is preferably higher than the redox potential of a hypobromite ion (BrO⁻)/bromide ion (Br⁻) system. The “redox potential of a hypobromite ion/bromide ion system” is the redox potential in the following reaction formula (3) and means an electric potential in an equilibrium state between a hypobromite ion, which is an oxidant existing in the treatment liquid, and a bromide ion which is a reductant:

BrO⁻+2H₂O+2e⁻→Br⁻+2OH⁻ (3)

In other words, a condition in which the redox potential of an oxidizing agent is higher than the hypobromite ion/bromide ion redox potential means that the redox potential between the oxidizing agent and a chemical species generated by reduction of the oxidizing agent is higher than the redox potential between a hypobromite ion and a bromide ion system generated by reduction of the hypobromite ion.

By using such an oxidizing agent, Br can be oxidized into a hypobromite ion. The redox potential between the oxidizing agent optionally contained in the treatment liquid and a chemical species generated by reduction of the oxidizing agent varies depending on the concentration of the oxidizing agent and that of the chemical species generated by reduction of the oxidizing agent as well as the temperature, the pH and the like of the treatment liquid; however, regardless of these conditions, it is only necessary that the redox potential between the oxidizing agent and a chemical species generated by reduction of the oxidizing agent be higher than the redox potential of the BrO⁻/Br⁻ system. Meanwhile, the oxidizing agent optionally contained in the treatment liquid is not particularly limited in terms of the upper limit of the redox potential between the oxidizing agent and a chemical species generated by reduction of the oxidizing agent, as long as it does not depart from the object of the present invention.

As the oxidizing agent optionally contained in the treatment liquid of the present embodiment, a hypochlorite ion (ClO⁻), ozone, an orthoperiodate ion, or a metaperiodate ion is preferably utilized since it does not contain any metal ion that causes a problem in semiconductor fabrication. Particularly, a hypochlorite ion is more preferred since it has a high solubility in the treatment liquid and stably exists in a solution, and its concentration is easily adjustable.

A hypochlorite ion, ozone, an orthoperiodate ion, and a metaperiodate ion are capable of re-oxidizing Br⁻ to a hypobromite ion in an alkaline treatment liquid (having a pH of 8 or higher and 14 or lower). This is also seen from the fact that, for example, the redox potential of the BrO⁻/Br⁻ system is 0.76 V while the redox potential of the ClO⁻/Cl⁻ system and that of the ozone/oxygen system are 0.89 V and 1.24 V, respectively. It is noted here that the above-described redox potentials are values measured against a standard hydrogen electrode at a pH of 14 (25° C.). Accordingly, in the treatment liquid of the present embodiment which contains a hypobromite ion and a hypochlorite ion or ozone, since a high hypobromite ion concentration can be maintained by oxidation of Br⁻ into a hypobromite ion, the etching rate of a transition metal can be stabilized.

The treatment liquid of the present embodiment which contains both a hypobromite ion and a hypochlorite ion has an extended etching rate stability time for ruthenium, and thus can be particularly preferably utilized. On the other hand, when an oxidizing agent having a weak oxidative power in an alkaline condition such as hydrogen peroxide is used, Br⁻ cannot be efficiently oxidized into a hypobromite ion; therefore, the treatment liquid has a low etching rate of ruthenium, and it is difficult to stabilize the etching rate of this transition metal.

When the treatment liquid of the present embodiment contains a hypochlorite ion, the concentration thereof is not limited within the gist of the present invention; however, it is preferably 0.1 μmol/L or more and 4 mol/L or less. When the concentration of the hypochlorite ion is less than 0.1 μmol/L, Br⁻ cannot be efficiently oxidized, and the etching rate of ruthenium is thus reduced. Meanwhile, it is not appropriate to add the hypochlorite ion in an amount of greater than 4 mol/L since it deteriorates the stability of the hypochlorite ion. From the standpoint of achieving both inhibition of the RuO₄ gas generation and a sufficient etching rate of ruthenium, a total concentration of the hypobromite ion and other oxidizing agent is more preferably 1 μmol/L or more and 2 mol/L or less, most preferably 10 μmol/L or more and 2 mol/L or less.

When the ratio of the hypochlorite ion with respect to the hypobromite ion is high, a reaction between the hypochlorite ion and the hypobromite ion causes a reaction of converting the hypobromite ion into a bromate ion to proceed, as a result of which the hypobromite ion concentration is reduced. A reduction in the hypobromite ion concentration leads to a reduction in the etching rate of a transition metal; therefore, it is important to stabilize the hypobromite ion concentration. The hypobromite ion concentration can be stabilized by controlling the quantitative ratio of the hypobromite ion and the hypochlorite ion that are contained in the treatment liquid.

The quantitative ratio of the hypobromite ion and the hypochlorite ion that are contained in the treatment liquid is preferably determined taking into consideration the rate of decrease in the hypobromite ion, more precisely the rate at which Br⁻ is generated by reduction reaction and/or decomposition reaction of the hypobromite ion, and the rate of oxidation reaction from Br⁻ to BrO⁻ that is caused by the hypochlorite ion; however, in reality, since these reactions are affected by plural factors in a complex manner, it is difficult to determine an appropriate quantitative ratio of the hypobromite ion and the hypochlorite ion. Nevertheless, as long as the ratio of the hypobromite ion molar concentration with respect to the hypochlorite ion molar concentration of (hypobromite ion molar concentration/hypochlorite ion molar concentration) is in a range of 0.001 to 100. Br⁻ generated by reduction reaction or decomposition reaction of BrO⁻ can be re-oxidized back to BrO⁻ by the hypochlorite ion, so that the etching rate of a transition metal is stabilized.

A method of generating the above-described hypochlorite ion is not particularly limited, and a hypochlorite ion generated by any method can be suitably used in the treatment liquid of the present embodiment. As a method of generating a hypochlorite ion, for example, a method of adding a hypochlorite, or a method of blowing chlorine gas can be suitably employed. Between these methods, the method of adding a hypochlorite to the treatment liquid is more preferred since it allows to control the hypochlorite ion concentration more easily and makes it easier to handle the hypochlorite. Examples of the hypochlorite include tetraalkylammonium hypochlorites, sodium hypochlorite, potassium hypochlorite, calcium hypochlorite, magnesium hypochlorite, and hypochlorous acid. Thereamong, a tetraalkylammonium hypochlorite or hypochlorous acid is particularly preferred from the standpoint of not containing any metal that causes a problem in semiconductor fabrication, and a tetraalkylammonium hypochlorite is most preferred since it can stably exist even at a high concentration.

As the above-described tetraalkylammonium hypochlorite, a tetraalkylammonium hypochlorite which contains a tetraalkylammonium ion having carbon number of 1 to 20 per alkyl group is preferred. Specific examples thereof include tetramethylammonium hypochlorite, ethyltrimethylammonium hypochlorite, tetraethylammonium hypochlorite, tetrapropylammonium hypochlorite, tetrabutylammonium hypochlorite, tetrapentylammonium hypochlorite, and tetrahexylammonium hypochlorite, among which tetramethylammonium hypochlorite, ethyltrimethylammonium hypochlorite, and tetraethylammonium hypochlorite are more preferred since they contain a large amount of hypochlorite ion per unit weight. Tetramethylammonium hypochlorite is most preferred since a high-purity product thereof is readily available.

A method of producing the above-described tetramethylammonium hypochlorite is not particularly limited, and tetramethylammonium hypochlorite produced by a widely known method, examples which include a method of blowing chlorine into tetramethylammonium hydroxide, a method of mixing hypochlorous acid and tetramethylammonium hydroxide, a method of substituting cations in a hypochlorite solution with tetramethylammonium using an ion exchange resin, and a method of mixing a distillate of a hypochlorite-containing solution with tetramethylammonium hydroxide, can be preferably used.

The hypohalite ion concentration in the treatment liquid can be determined by calculation at the time of producing the treatment liquid, or can be verified by a known method. As a measurement method, specifically, absorption attributed to a hypohalite ion is checked by UV-visible absorptiometry, and the hypohalite ion concentration can be determined from the intensity of the thus obtained absorption peak and a calibration curve prepared using a hypohalite ion solution having a known concentration. The hypochalite ion concentration can be determined by a titration method as well.

When the treatment liquid of the present embodiment contains an orthoperiodate ion or a metaperiodate ion, the concentration thereof is not limited within the gist of the present invention; however, it is preferably 0.1 μmol/L or more and 4 mol/L or less. When the concentration of the orthoperiodate ion or the metaperiodate ion is less than 0.1 μmol/L, Br⁻ cannot be efficiently oxidized, and the etching rate of ruthenium is thus reduced. Meanwhile, it is not appropriate to add the orthoperiodate ion or the metaperiodate ion in an amount of more than 4 mol/L since it deteriorates the stability of the orthoperiodate ion or the metaperiodate ion. From the standpoint of achieving both inhibition of the RuO₄ gas generation and a sufficient etching rate of ruthenium, even when the treatment liquid of the present embodiment contains an orthoperiodate ion or a metaperiodate ion, the concentration of all oxidizing agents is more preferably 1 μmoL/L or more and 2 mol/L or less, most preferably 10 μmol/L or more and 2 mol/L or less.

### (pH of Treatment Liquid and Organic Alkali)

The pH of the treatment liquid for a transition metal semiconductor according to the present embodiment is preferably 8 or higher and 14 or lower, more preferably 8 or higher and 13 or lower, most preferably 10 or higher and 13 or lower. As long as the pH of the treatment liquid is 8 or higher and 14 or lower, the treatment liquid can efficiently etch a transition metal. When the pH of the treatment liquid is lower than 8, decomposition of the hypobromite ion occurs, and etching is thus unlikely to proceed. Meanwhile, when the pH of the treatment liquid is higher than 14, decomposition of the above-described oxidizing agent occurs, potentially causing oxidation of a bromine-containing compound to be inconsistent. This means that the etching rate of a transition metal is not consistent, and is thus needs to be avoided since it complicates the process control in a semiconductor fabrication process.

In order to adjust the pH of the treatment liquid, an acid or an alkali can be added to the treatment liquid. The acid can be either an inorganic acid or an organic acid, and examples thereof include hydrofluoric acid, hydrochloric acid, hydrobromic acid, nitric acid, sulfuric acid, peroxodisulfuric acid, and carboxylic acids such as formic acid and acetic acid. In addition, a widely known acid used in a semiconductor treatment liquid can be used without any limitation. As the alkali, it is preferred to use an organic alkali since it does not contain any metal ion that causes a problem in semiconductor fabrication. The organic alkali is, for example, a tetraalkylammonium hydroxide composed of a tetraalkylammonium ion and a hydroxide ion. Examples of the tetraalkylammonium hydroxide include tetramethylammonium hydroxide, ethyltrimethylammonium hydroxide, tetraethylammonium hydroxide, tetrapropylammonium hydroxide, and tetrabutylammonium hydroxide. Thereamong, the organic alkali is preferably a tetraalkylammonium hydroxide since it contains a large amount of hydroxide ion per unit weight and a high-purity product thereof is readily available, and the organic alkali is more preferably tetramethylammonium hydroxide or ethyltrimethylammonium hydroxide. Further, as desired, a pH buffer can be added to the treatment liquid. As the pH buffer, any widely known pH buffer can be used, and examples thereof include phosphoric acid, boric acid, carbonic acid, oxalic acid, and salts of these acids.

### (Tetraalkylammonium Ion)

In order to adjust the pH of the treatment liquid, an acid or an alkali can be added to the treatment liquid. As the alkali, it is preferred to use an organic alkali since it does not contain any metal ion that causes a problem in semiconductor fabrication. Among organic alkalis, an onium salt containing an onium ion is preferably used. The onium salt is, for example, a tetraalkylammonium hydroxide composed of a tetraalkylammonium ion and a hydroxide ion. The carbon number in an alkali of the tetraalkylammonium ion derived from the tetraalkylammonium hydroxide is, for example, 1 to 20, and it is preferably 1 to 10. Examples of the tetraalkylammonium hydroxide include tetramethylammonium hydroxide, ethyltrimethylammonium hydroxide, tetraethylammonium hydroxide, tetrapropylammonium hydroxide, and tetrabutylammonium hydroxide. Thereamong, the organic alkali is preferably a tetraalkylammonium hydroxide since it contains a large amount of hydroxide ion per unit weight and a high-purity product thereof is readily available, and the organic alkali is more preferably tetramethylammonium hydroxide or ethyltrimethylammonium hydroxide.

In the treatment liquid, the above-described tetraalkylammonium ion can be used singly, or in combination of two or more thereof.

The treatment liquid of the present embodiment can further contain a RuO₄ gas generation inhibitor. By incorporating a RuO₄ gas generation inhibitor into the treatment agent, the generation of RuO₄ gas from ruthenium oxide dissolved in the treatment liquid can be inhibited in a treatment of a ruthenium-containing wafer. The RuO₄ gas generation inhibitor is preferably, for example, one which contains a compound having a ligand coordinated with RuO₄, RuO₄⁻, RuO₄²⁻ or the like. Specific examples of the compound having a ligand coordinated with RuO₄, RuO₄⁻, RuO₄²⁻ or the like include: compounds having a carboxyl group or a carbonyl group, which are typified by oxalic acid, dimethyl oxalate, 1,2,3,4,5,6-cyclohexane hexacarboxylic acid, succinic acid, acetic acid, butane-1,2,3,4-tetracarboxylic acid, dimethyl malonate, glutaric acid, diglycolic acid, citric acid, malonic acid, 1,3-adamantane dicarboxylic acid, and 2,2-bis(hydroxymethyl)propionic acid; and nitrogen-containing heterocyclic compounds typified by pyridine compounds, piperazine compounds, triazole compounds, pyrazole compounds, and imidazole compounds. Further, examples of the RuO₄ gas generation inhibitor include onium salts composed of an onium ion and a bromine-containing ion. The RuO₄ gas generation inhibitor is more preferably the below-described RuO₄ gas generation inhibitor that contains an onium salt composed of an onium ion and a bromine-containing ion, since it exerts a high effect of inhibiting the generation of RuO₄ gas, has a low content of metals that cause a problem in semiconductor fabrication, and can be industrially produced at a low cost.

### (Solvent)

As a solvent of the treatment liquid of the present embodiment, water is most preferably used. The water contained in the treatment liquid of the present embodiment is preferably water from which metal ions, organic impurities, particles and the like have been removed by distillation, ion exchange, filtration, or various adsorption treatments, and the water is particularly preferably pure water or ultrapure water. Such water can be obtained by a known method widely utilized in semiconductor fabrication.

Alternatively, an organic solvent can be used as long as it allows a hypohalite ion to exist stably. As the organic solvent, for example, acetonitrile or sulfolane is used.

Further, as the solvent, water and an organic solvent can be used in combination as well. The use of water and an organic solvent in combination allows oxidation of a transition metal to proceed relatively slowly, so that oxidation of wiring and the like of a circuit-forming part can be inhibited. When water and an organic solvent are used in combination, the mass ratio of water and the organic solvent (water/organic solvent) can be about 60/40 to 99.9/0.1.

### (Other Additives)

In the treatment liquid of the present embodiment, as desired, other additives that are conventionally used in semiconductor treatment liquids can be incorporated within a range that does not hinder the object of the present invention. As such other additives, for example, an acid, a metal corrosion inhibitor, an aqueous organic solvent, a fluorine compound, an oxidizing agent, a reducing agent, a complexing agent, a chelating agent, a surfactant, an antifoaming agent, a pH modifier, and a stabilizing agent can be added. These additives can be added singly, or in combination of two or more thereof.

### (Method of Producing Treatment Liquid)

A method of producing the semiconductor treatment liquid according to the present embodiment is not particularly limited. For example, the treatment liquid of the present embodiment can be preferably produced by the production method according to a third embodiment of the present invention. Alternatively, the treatment liquid of the present embodiment can be produced by adding hypobromite ion, hypobromous acid, and/or a hypobromite to a solvent such as water at a desired concentration, further adding an additive(s) as required, and subsequently adjusting the resultant to have a desired pH. The treatment liquid of the present embodiment can also be produced by preparing plural solutions in which components are separately contained (hereinafter, also referred to as “preparation materials”) and mixing these preparation materials immediately before a treatment of a semiconductor wafer. In cases where plural preparation materials are prepared and mixed to produce the treatment liquid of the present embodiment, the components contained in the preparation materials can be those which react with each other to yield a hypobromite ion after the preparation materials are mixed. The pH, the formulation, and the like of the treatment liquid of the present embodiment may change with time, resulting a change in the etching performance such as etching rate. Therefore, from the standpoint of inhibiting deterioration of the etching performance caused by such change with time, a production method in which plural preparation materials are prepared and the treatment liquid of the present embodiment is obtained by mixing the preparation materials immediately before a treatment of a semiconductor wafer is also preferred. With regard to the number of the plural preparation materials to be prepared, the preparation materials can be prepared for each component; however, taking into consideration the ease of operation and the like in mixing, it is preferred to prepare two kinds of preparation materials.

A method of producing the treatment liquid of the present embodiment in which two kinds of preparation materials, a first solution (preparation material) and a second solution (preparation material), are prepared and these preparation materials are mixed to obtain the treatment liquid immediately before a treatment of a semiconductor wafer will now be described in detail.

### (Preparation Materials)

An advantage of using two kinds of preparation materials which are the first solution (preparation material) and the second solution (preparation material) is that, for example, the stability of etching performance by the treatment liquid containing a hypobromite ion is thereby improved. In other words, in cases where the treatment liquid is composed of a single solution, the etching performance thereof such as etching rate may be modified due to decomposition of the hypobromite ion during the lapse of time from the production of the hypobromite ion to a treatment of a semiconductor wafer at a semiconductor fabrication plant. On the other hand, in the case of preparing and mixing two kinds of preparation materials, which are the first solution (preparation material) and the second solution (preparation material), to produce the treatment liquid and generate a hypobromite ion, since a hypobromite ion-containing treatment liquid is produced immediately before a treatment of a semiconductor wafer at a semiconductor fabrication plant, decomposition of the hypobromite ion can be inhibited, so that stable etching performance can be exerted. Particularly, when the treatment liquid of the present embodiment is to be used in the etch-back step or the like, since microfabrication and precise control of the etching rate and the surface roughness are required, the treatment liquid preferably takes the above-described mode.

Accordingly, in the case of preparing the treatment liquid as two kinds of preparation materials which are the first solution (preparation material) and the second solution (preparation material), from the standpoint of the storage stability of the preparation materials themselves as well as from the standpoint of enabling to stably reduce the metal surface roughness, the components in the two solutions constituting the preparation materials are preferably as follows.
first solution (preparation material): a solution containing at least one anion species selected from a bromate ion, a bromite ion, and a bromide ion
second solution (preparation material): a solution containing a hypohalite ion

In order to generate a hypobromite ion by mixing two kinds of preparation materials which are the above-described first solution (preparation material) and second solution (preparation material), it is only necessary that a bromide ion be contained in the first solution (preparation material) and a hypohalite ion having a higher oxidative power than the bromide ion in the first solution (preparation material) be contained in the second solution (preparation material). One example of such a hypohalite ion is a hypochlorite ion. Specifically, for the production of a hypobromite ion-containing treatment liquid, a bromide ion-containing liquid and a hypochlorite ion-containing liquid can be used as the first solution (preparation material) and the second solution (preparation material), respectively. The hypochlorite ion-chloride ion redox potential (0.89 V (at 25° C., pH 14, vs standard hydrogen electrode) is higher than the hypobromite ion-bromide ion redox potential (0.76V (the same as above)); therefore, by mixing the first solution and the second solution, the bromite ion is oxidized by the hypochlorite ion, as a result of which a hypobromite ion can be generated, and a hypobromite ion-containing treatment liquid can thus be produced. In this process, the hypochlorite ion is reduced to a chloride ion. The bromide ion contained in the first solution (preparation material) can be added in the form of a bromide ion as described below, or can be a bromide ion generated by decomposition of a bromate ion, a bromite ion, and/or a hypobromite ion.

### (Method of Preparing First Solution (Preparation Material))

In the present embodiment, a method of preparing the first solution (preparation material) is not particularly limited. Specifically, the first solution (preparation material) of the present embodiment can be prepared by adding at least one anion species selected from a bromate ion, a bromite ion, and a bromide ion to a solvent such as water. As required, other additives and the like may also be added to the first solution (preparation material). In cases whom two kinds of preparation materials, which are the first solution (preparation material) and the second solution (preparation material), are mixed to generate a hypobromite ion and the first solution (preparation material) contains a bromide ion, the hypobromite ion can be generated by, for example, dissolving a salt or the like, which yields the ion when dissolved, into the first solution. Examples of a raw material of the bromide ion include metal salts such as sodium bromide, organic salts such as tetraalkylammonium bromide, bromine gas, and hydrogen bromide. Thereamong, organic salts, bromine gas, and hydrogen bromide are preferred since they do not contain any metal that causes a reduction in the yield in semiconductor fabrication. In consideration of the industrial availability and the ease of handling, a raw material of the bromide ion is more preferably an organic salt. Among organic salts, from the standpoint of stability, purity and cost, for example, an onium ion-containing organic salt such as tetramethylammonium bromide, ethyltrimethylammonium bromide, tetraethylammonium bromide, or tetrapropylammonium bromide can be particularly preferably used.

As the organic salt used in the present embodiment, for example, a tetraalkylammonium bromide produced from a tetraalkylammonium ion and a bromide ion can be used. As a method of producing the tetraalkylammonium bromide, it only needs to mix a tetraalkylammonium hydroxide-containing aqueous solution with a bromide ion-containing aqueous solution, or a bromine-containing gas that yields a bromide ion when dissolved in water, such as hydrogen bromide. Examples of the tetraalkylammonium hydroxide used for producing the tetraalkylammonium bromide include tetramethylammonium hydroxide, ethyltrimethylammonium hydroxide, tetraethylammonium hydroxide, tetrapropylammonium hydroxide, and tetrabutylammonium hydroxide. Thereamong, the tetraalkylammonium hydroxide is more preferably tetramethylammonium hydroxide or ethytrimethylammonium hydroxide since it contains a large amount of hydroxide ion per unit weight and a high-purity product thereof is readily available. Examples of a bromine ion source that generates the bromide ion used for producing the tetraalkylammonium bromide include hydrogen bromide, lithium bromide, sodium bromide, potassium bromide, rubidium bromide, cesium bromide, and ammonium bromide. Thereamong, hydrogen bromide is preferred since it contains substantially no metal and is easy to obtain industrially, and a high-purity product thereof is readily available.

The concentration of the at least one anion species selected from a bromate ion, a bromite ion, and a bromide ion in the first solution (preparation material) can be set as appropriate such that it gives a desired concentration when the treatment liquid of the present embodiment is produced by mixing the first solution with the second solution. For example, when mixing of the first solution (preparation material) and the second solution (preparation material) does not yield a hypobromite ion, the concentration of the anion species in the first solution (preparation material) can be set taking into consideration the volume of the treatment liquid obtained after the mixing. On the other hand, when mixing of the first solution (preparation material) and the second solution (preparation material) yields a hypobromite ion, the concentration of bromide ion in the first solution (preparation material) can be set taking into consideration the amount of the bromide ion consumed for the generation of a hypobromite ion.

The pH of the first solution is not particularly limited, and can be set as appropriate such that it gives a desired pH when the treatment liquid of the present embodiment is produced by mixing the first solution with the second solution. From the standpoint of inhibiting a change in the pH after the mixing, the pH of the first solution is desirably 7 to 14, more preferably 8 to 14. A solution having a pH in this range can reduce a decrease in the pH that occurs when the solution is mixed with the below-described second solution, and this enables to stably produce, store, and use the treatment liquid of the present embodiment. When the first solution has a pH of lower than 8, the pH and the amount of the first solution can be adjusted such that, when the first solution is mixed with the second solution, the resulting treatment liquid has an alkaline pH. As other components to be contained in the first solution, those solvents, other additives, and pH modifier that are described above for the treatment liquid of the present embodiment are preferably used.

### (Method of Preparing Second Solution (Preparation Material))

In the present invention, a method of preparing the second solution (preparation material) is not particularly limited. Specifically, the second solution (preparation material) of the present embodiment can be prepared by adding a hypohalite ion to a solvent such as water, and further adding an additive(s) as required. As for the hypohalite ion, for example, sodium hypochlorite, sodium hypobromite, a tetraalkylammonium hypochlorite, and a tetraalkylammonium hypobromite can be used. Thereamong, it is preferred to use a tetraalkylammonium hypochlorite or a tetraalkylammonium hypobromite which does not contain any metal that causes a reduction in the yield in a semiconductor formation process. This tetraalkylammonium hypohalite can be prepared by a known method. For example, an aqueous solution that contains a tetraalkylammonium hypochlorite or a tetraalkylammonium hypobromite can be obtained by preparing an aqueous tetraalkylammonium hydroxide solution and subsequently blowing chlorine or bromine thereinto, respectively. Alternatively, a solution that contains a tetraalkylammonium hypochlorite or a tetraalkylammonium hypobromite can be prepared by a method in which a tetraalkylammonium hydroxide solution is brought into contact with a cation exchange-type ion exchange resin to convert cations in the ion exchange resin into tetraalkylammonium ions, and a sodium hypochlorite solution or a sodium hypobromite solution is subsequently circulated in the resultant to exchange sodium ions with the tetraalkylammonium ions.

The concentration of the hypohalite ion in the second solution (preparation material) can be set as appropriate such that it gives a desired concentration when the treatment liquid of the present embodiment is produced by mixing the second solution with the first solution. For example, when mixing of the first solution (preparation material) and the second solution (preparation material) does not yield a hypobromite ion, the concentration of the hypohalite ion in the second solution (preparation material) can be set taking into consideration the volume of the treatment liquid obtained after the mixing. On the other hand, when mixing of the first solution (preparation material) and the second solution (preparation material) yields a hypobromite ion, the concentration of the hypohalite ion in the second solution (preparation material) can be set taking into consideration the amount of the hypohalite ion consumed for the generation of a hypobromite ion.

The pH of the second solution is not particularly limited, and can be set as appropriate such that it gives a desired pH when the treatment liquid of the present embodiment is produced by mixing the second solution with the first solution. From the standpoint of inhibiting a change in the pH after the mixing, the pH of the second solution is desirably 7 to 14, more preferably 10 to 14, particularly preferably 12 to 14. A solution having a pH in this range can reduce a decrease in the pH that occurs when the solution is mixed with the above-described first solution, and this enables to stably produce, store, and use the treatment liquid of the present embodiment. As other components to be contained in the second solution, those solvents, other additives, and pH modifier that are described above for the treatment liquid of the present embodiment are preferably used.

The treatment liquid and the preparation materials according to the present embodiment are preferably produced and stored in a low-temperature, light-shielded, and amine-free condition. The production and storage in a low-temperature, light-shielded, and amine-free condition is expected to have an effect of inhibiting decomposition of the oxidizing agent and the anion species in the treatment liquid. In addition, by producing and storing the treatment liquid and the preparation materials in a vessel filled with an inert gas, contamination with carbon dioxide can be inhibited, so that the stability of the treatment liquid can be maintained. Further, the inner surface of the vessel. i.e. the surface coming into contact with the treatment liquid, is preferably formed of glass or an organic polymer material. This is because contamination with impurities such as metals, metal oxides, and organic matters can be further reduced when the inner surface of the vessel is formed of glass or an organic polymer material.

### (Formulations of Preparation Materials)

The concentrations of the respective components contained in the two kinds of preparation materials used in the method of producing the treatment liquid of the present embodiment, which are the first solution (preparation material) and the second solution (preparation material), are not particularly limited, and the preparation materials can be prepared such that the treatment liquid obtained after mixing them have a desired formulation.

Specifically, when the treatment liquid contains 0.1 μmol/L or more and less than 0.001 mol/L of a hypobromite ion along with, as anion species, 0.01 μmol/L or more and less than 5.0 mol/L of a bromide ion, 0.01 μmol/L or more and less than 5.0 mol/L of a bromite ion, and 0.01 μmol/L or more and less than 5.0 mol/L of a bromate ion, the first solution (preparation material) can be a solution which contains, as anion species, 0.22 μmol/L or more and less than 10.002 mol/L of a bromide ion, 0.02 μmol/L or more and less than 10.0 mol/L of a bromite ion, and 0.02 μmol/L or more and less than 10.0 mol/L of a bromate ion, while the second solution (preparation material) can be a solution which contains 0.2 μmol/L to 0.002 mol/L of a hypochlorite ion, and the treatment liquid of a semiconductor wafer can be produced by mixing these preparation materials before treating the semiconductor wafer.

Alternatively, when the treatment liquid contains 0.1 μmol/L or more and less than 0.001 mol/L of a hypobromite ion and 0.1 μmol/L or more and 4 mol/L or less of a hypochlorite ion as hypohalite ions and 0.01 μmol/L or more and less than 5.0 mol/L of a bromate ion as an anion species along with, as other components, 0.1 μmol/L or more and less than 5.0 mol/L of a chloride ion and 0.01 μmol/L or more and less than 5.0 mol/L of a chlorate ion, the first solution (preparation material) can be a solution which contains 0.2 μmol/L or more and less than 0.002 mol/L of a bromide ion, less than 9.998 mol/L of a chloride ion, 0.02 μmol/L or more and less than 10.0 mol/L of a chlorate ion, and 0.02 μmol/L or more and less than 10.0 mol/L of a bromate ion, while the second solution (preparation material) can be a solution which contains 0.4 μmol/L to 8.002 mol/L of a hypochlorite ion, and the treatment liquid of a semiconductor wafer can be produced by mixing these preparation materials before treating the semiconductor wafer.

### (Method of Mixing Preparation Materials)

As a method of mixing the first solution (preparation material) and the second solution (preparation material), any method widely known as a method of mixing semiconductor chemical solutions can be employed. For example, a method of mixing solution using a mixing tank, a method of mixing solutions inside a pipe of a semiconductor fabrication apparatus (in-line mixing), or a method of mixing plural solutions by simultaneously pouring them onto a wafer can be suitably employed. When a hypobromite ion is generated by mixing the first solution (preparation material) and the second solution (preparation material), from the standpoint of ensuring the generation of the hypobromite ion, it is preferred to mix the preparation materials in advance and allow the hypobromite ion to be sufficiently generated before bringing the preparation materials into contact with a semiconductor wafer.

A temperature at which the preparation materials are mixed is not particularly limited as long as the treatment liquid obtained after the mixing is homogeneous and, usually, the temperature may be set as appropriate in a range of 0 to 80° C. When a hypobromite ion is generated by mixing the preparation materials, it is preferred that the hypobromite ion be generated as quickly as possible; therefore, the shorter the mixing time, the more preferred it is. In order to shorten the mixing time, for example, the temperature during the mixing can be increased; however, a higher temperature tends to cause decomposition of the second solution or the hypohalite ions contained in the treatment liquid obtained after the mixing to proceed further. From this reason, when a hypobromite ion is generated by mixing the preparation materials, the temperature during the mixing of the preparation materials is more preferably 10 to 60° C., most preferably 20 to 50° C.

Further, with regard to the mixing time of the preparation materials, when a hypobromite ion is not generated by mixing the first solution (preparation material) and the second solution (preparation material), the mixing can be performed until the resulting treatment liquid has uniform temperature and composition concentration and, usually, the mixing time can be set as appropriate in a range of 30 minutes or less. On the other hand, when a hypobromite ion is generated by mixing the first solution (preparation material) and the second solution (preparation material), the longer the mixing time, the more preferred it is for ensuring the generation of the hypobromite ion; however, from the standpoint of the throughput, the mixing time can be usually set as appropriate in a range of 60 minutes or less.

Further, in the treatment liquid of the present embodiment, the content of each metal, specifically the content of each of sodium, potassium, aluminum, magnesium, iron, nickel, copper, silver, cadmium, and lead, is preferably 1 ppb or less. For the inhibition of contamination with these metals, it is possible to use a reactor, a pipe and the like in which the surface coming into contact with a solution is formed of an organic polymer material. As the organic polymer material, for example, any of vinyl chloride resins (soft and hard vinyl chloride resins), nylon resins, silicone resins, polyolefin resins (polyethylenes and polypropylenes), and fluorine resins can be used. Thereamong, a fluorine resin is preferred considering the ease of molding, solvent resistance, and low elution of impurities.

In the treatment liquid of the present embodiment as well as in a halogen oxyacid salt, an oxidizing agent, a tetraalkylammonium salt, an acid, an alkali, water, a solvent, other additives and the like that are used in the treatment liquid, the content of ammonia and amines is preferably small. This is because ammonia and amines existing in the treatment liquid react with the oxidizing agent, halogen oxyacid salt, halogen oxyacid ion and the like to deteriorate the stability of the treatment liquid. For example, when tetramethylammonium hydroxide is used as the alkali, ammonia and amines that are contained in this basic compound, particularly trimethylamine, may cause a reduction in the stability of the treatment liquid. Therefore, when tetramethylammonium hydroxide is used in the treatment liquid of the present embodiment, a total amount of amines contained in the basic compound is preferably, for example, 100 ppm or less. As long as the total amount of amines is 100 ppm or less, the reactions of the amines with an oxidizing agent, a bromine-containing compound, and a chemical species that is generated from the bromine-containing compound and used for etching a transition metal only have a minor effect, so that the stability of the treatment liquid is not deteriorated.

The production of the treatment liquid of the present embodiment is preferably carried out in a light-shielded condition so as to prevent the halogen oxyacid ion, the oxidizing agent, other additives and the like from being decomposed by light.

Further, in the production of the treatment liquid of the present embodiment, it is preferred to prevent carbon dioxide from dissolving into the treatment liquid. When the treatment liquid of the present embodiment is alkaline, carbon dioxide readily dissolves into the treatment liquid and can cause a change in the pH. A change in the pH of the treatment liquid not only causes a variation in the etching rate of a transition metal, but also deteriorates the stability of the treatment liquid. The amount of carbon dioxide dissolving into the treatment liquid can be reduced by a method of, for example, purging carbon dioxide contained in a production apparatus with an inert gas flow, or carrying out the reaction in an inert gas atmosphere. As long as the amount of carbon dioxide in the production apparatus is 100 ppm or less, the effects caused by dissolution of carbon dioxide are negligible.

### (Storage of Treatment Liquid)

The treatment liquid of the present embodiment is preferably stored in a low-temperature and/or light-shielded condition. Storing the treatment liquid in a low-temperature and/or light-shielded condition is expected to have an effect of inhibiting decomposition of the oxidizing agent, the hypobromite ion and the like that are contained in the treatment liquid. In addition, by storing the treatment liquid in a vessel whose surface coming into contact with a solution is formed of an organic polymer material, and/or storing the treatment liquid in a vessel filled with an inert gas and thereby inhibiting contamination with carbon dioxide, the stability of the treatment agent can be maintained.

By the above-described production method, the semiconductor wafer treatment liquid of the present embodiment can be produced. Not only the use of the semiconductor wafer treatment liquid of the present embodiment improves the wafer processing efficiency per unit time, but also the semiconductor wafer treatment liquid of the present embodiment can be preferably used as a treatment liquid for the metal etch back step in a semiconductor fabrication process where, for example, precise control of etching is required for a wiring material. In addition, since the treatment liquid also has the same effect on metals other than ruthenium, it can be used as an etching liquid for not just ruthenium but also other metals contained in a semiconductor wafer.

### (Use of Treatment Liquid)

By using the treatment liquid of the present embodiment, a transition metal adhering to a surface portion, an edge portion, and a back surface portion of a semiconductor wafer can be etched at a sufficient etching rate in a stable manner. In addition, the flatness of the metal surface can be maintained after etching. The term “sufficient etching rate” used herein means an etching rate at which, when microfabrication of a transition metal is done by etching in a semiconductor fabrication process, the amount of etched transition metal can be controlled by the etching time and the flatness can be maintained after the etching. In other words, the “sufficient etching rate” refers to an etching rate at which a transition metal can be microfabricated within a practical time in a semiconductor fabrication process and the flatness of the metal surface can be maintained. Specifically, the “sufficient etching rate” means an etching rate of 10 Å/min or higher when the transition metal to be etched is ruthenium, or an etching rate of 50 Å/min or higher when the transition metal to be etched is tungsten, molybdenum, or chromium. As long as the etching rate of ruthenium, tungsten, molybdenum, or chromium satisfies the above-described value, the treatment liquid of the present embodiment can be preferably used in the etching step, the residue removal step, the washing step, the CMP step, and the like. In cases where a transition metal needs to be etched faster than the above-described etching rate, for example, the hypobromite ion concentration, the hypochlorite ion concentration, the bromine-containing compound concentration, and the oxidizing agent concentration in the treatment liquid, as well as the pH of the treatment liquid, the treatment temperature, and the method of bringing the treatment liquid into contact with a wafer can be selected as appropriate.

As described above, the semiconductor wafer treatment liquid of the present embodiment not only improves the wafer processing efficiency per unit time, but also can be preferably used as a treatment liquid for the metal etch back step in a semiconductor fabrication process where, for example, precise control of etching is required for a wiring material. In addition, since the treatment liquid also has the same effect on metals other than ruthenium, it can be used as an etching liquid for not just ruthenium but also other metals contained in a semiconductor wafer.

A temperature at which a metal is etched with the treatment liquid of the present embodiment is not particularly limited, and can be determined as appropriate taking into consideration the etching rate of the metal, the stability of the treatment liquid, and the like. The stability of the treatment liquid tends to be deteriorated as the temperature increases; therefore, a lower treatment temperature is more preferred. On the other hand, the etching rate of a metal tends to be increased as the temperature increases. From the standpoint of obtaining both a sufficient stability of the treatment liquid and a sufficient etching rate, the temperature at which a metal is etched is preferably 10° C. to 90° C., more preferably 15° C. to 70° C., most preferably 20° C. to 60° C.

The treatment liquid of the present embodiment can be preferably used for treating a substrate provided with a transition metal-containing film. Examples of the substrate include silicon wafers, glasses, plastics, and non-silicon semiconductor substrates, on which a transition metal-containing film is formed. By using the treatment liquid of the present embodiment, the transition metal-containing films on these substrates can be etched at a sufficient rate. This enables to etch (dissolve) the transition metals existing on these substrates and to process and/or remove the transition metals, whereby formation of a semiconductor element, formation of a wiring, control of the metal film thickness, formation of an electrode, and the like can be carried out.

Specific examples of a metal contained in a semiconductor wafer to which the treatment liquid of the present embodiment is applied include Ru, Rh, Ti, Ta, Co, Cr, Hf, Os, Pt, Ni, Mn, Cu, Zr, La, Mo, and W. The treatment liquid of the present embodiment can be applied regardless of whether these metals are in the form of a single metal species or an alloy of plural metal species. Among these metals, the treatment liquid of the present embodiment can be preferably used for those metals that are useful as a wiring layer, such as Ru, Rh, Co, Cu, Mo, and W. Films of these metals can be formed by any method, and a method widely known in semiconductor fabrication process, such as CVD, ALD, PVD, sputtering, or plating, can be utilized.

The above-described metals may also be in the form of an intermetallic compound, an ionic compound, or a complex. Further, the metals may be exposed on the wafer surface, or covered by other metal, a metal oxide film, an insulating film, a resist, or the like. Even if the metals are covered by other material, a sufficient etching rate and a satisfactory surface roughness can both be obtained when the metals are brought into contact with the treatment liquid of the present embodiment and thereby dissolved.

For example, in the metal wiring formation step, the treatment liquid of the present embodiment is used in the following manner. First, a substrate made of a semiconductor (e.g., Si) is prepared. This substrate is oxidized to form a silicon oxide film thereon. Subsequently, an interlayer insulating film composed of a low-dielectric-constant (Low-k) film is formed, and via-holes are formed thereon at prescribed intervals. Thereafter, a metal is embedded into the via-holes by thermal CVD to further form a metal film. This metal film is treated with the treatment liquid of the present embodiment, whereby the metal film can be planarized while a sufficient etching rate is maintained.

A method of bringing the treatment liquid of the present embodiment into contact with a semiconductor wafer on which the above-described metal layer is formed is not particularly limited. For example, the treatment liquid of the present embodiment can be poured over the semiconductor wafer while rotating the semiconductor wafer, or the semiconductor wafer can be immersed into the treatment liquid of the present embodiment in a container.

A treatment time of etching a metal with the treatment liquid of the present embodiment is in a range of 0.1 to 120 minutes, preferably 0.3 to 60 minutes, and the treatment time can be selected as appropriate in accordance with the etching conditions and the semiconductor element to be treated. After the use of the treatment liquid of the present embodiment, the treatment liquid can be removed by washing the semiconductor wafer surface, to which the treatment liquid has been brought into contact, using a rinsing liquid or the like. The rinsing liquid to be used after the use of the treatment liquid of the present embodiment is not particularly limited, and an organic solvent such as alcohol, or deionized water can be used. After the rinsing, the surface of the semiconductor wafer can be dried as required and then subjected to the subsequent steps, such as lamination of other wiring material thereon.

A second embodiment of the present invention is a RuO₄ gas generation inhibitor containing an onium salt composed of an onium ion and a bromine-containing ion, in which the concentration of the bromine-containing ion is 0.1 μmol/L or more and less than 0.001 mol/L. This RuO₄ gas generation inhibitor will now be described.

### (RuO₄ Gas Generation Inhibitor)

The term “RuO₄ gas generation inhibitor” used herein refers to a composition that inhibits the generation of RuO₄ gas when added to a liquid used for treating ruthenium (hereinafter, referred to as “ruthenium treatment liquid”), which composition is a liquid containing an onium salt composed of an onium ion and a bromine-containing ion.

The ruthenium treatment liquid refers to a liquid containing a component that comes into contact with ruthenium to cause a physical and/or chemical change to the ruthenium. Examples of the ruthenium treatment liquid include those liquids that are used in the steps of treating ruthenium in a semiconductor fabrication process, such as the etching step, the residue removal step, the washing step, and the CMP step, as well as those liquids that are used for washing ruthenium adhering to the chamber inner wall, the piping, and the like of each apparatus used in a semiconductor fabrication process.

Ruthenium treated with such a ruthenium treatment liquid is entirely or partially dissolved, dispersed, or precipitated in the ruthenium treatment liquid, and causes the generation of RuO₄ (gas) and/or RuO₂ (particles). When the RuO₁ gas generation inhibitor of the present embodiment is added to the ruthenium treatment liquid, anions such as RuO₄⁻ and RuO₄²⁻ (hereinafter, may be denoted as “RuO₄⁻ and the like”) existing in the ruthenium treatment liquid and the onium ion form ion pairs soluble in the ruthenium treatment liquid, as a result of which the generation of RuO₄ gas and/or RuO₂ particles can be inhibited. In addition, the effect of the bromine-containing ion of the onium salt contained in the RuO₄ gas generation inhibitor makes the formation of RuO₂ particles unlikely to occur.

### (Onium Salt)

The RuO₄ gas generation inhibitor of the present embodiment contains an onium salt for the inhibition of RuO₄ gas generation. The onium salt is composed of an onium ion and a bromine-containing ion. It is noted here that an onium ion is a polyatomic cation formed by addition of excess protons (hydrogen cations) to a monoatomic anion. Specific examples of the onium ion include cations such as an imidazolium ion, a pyrrolidinium ion, a pyridinium ion, a piperidinium ion, an ammonium ion, a phosphonium ion, a fluoronium ion, a chloronium ion, a bromonium ion, an iodonium ion, an oxonium ion, a sulfonium ion, a selenonium ion, a telluronium ion, an arsonium ion, a stibonium ion, and a bismuthonium ion. Thereamong, an ammonium ion, a phosphonium ion, and a sulfonium ion are preferred as the onium ion contained in the onium salt of the present embodiment since these onium ions stably exist in an alkaline solution, and the carbon chains and functional groups contained in these onium ions can be easily modified, so that the solubility, the bulkiness, and the charge density can be easily controlled. Further, a bromine-containing ion is an ion that contains bromine, and examples thereof include a bromite ion, a bromate ion, a perbromate ion, a hypobromite ion, and a bromide ion. When an onium ion contained in an onium salt is a polyvalent cation, at least one of anions contained in this onium salt is a bromine-containing ion. For example, when the onium salt contained in the RuO₄ gas generation inhibitor of the present embodiment contains a hexamethonium ion which is a divalent cation, at least one of its two counter anions can be a bromine-containing ion.

In order for the onium salt contained in the RuO₄ gas generation inhibitor of the present embodiment to exert its RuO₄ gas generation inhibitory capacity, the onium salt needs to be dissociated into an onium ion and a bromine-containing ion. This is because the onium ion generated by the dissociation of the onium salt interacts with RuO₄⁻ and the like and thereby inhibits the generation of RuO₄ gas. An onium salt containing a halogen-containing ion is easily dissociated, has excellent solubility, and is capable of stably providing an onium ion; therefore, such an onium salt can be used as the onium salt contained in the RuO₄ gas generation inhibitor of the present embodiment. Particularly, an onium salt containing a bromine-containing ion is more stable and easier to synthesize than an onium salt containing a chlorine-containing ion or a fluorine-containing ion; therefore, high-purity products thereof are industrially available at a low cost. In addition, an onium salt containing a bromine-containing ion is advantageous in that it gives a greater amount of onium ion per unit weight than an onium salt containing an iodine-containing ion. Moreover, since the bromine-containing ion interacts with a ruthenium surface. RuO₄⁻ and the like which are anions are kept away from the ruthenium surface, and this tends to make the formation of RuO₂ particles unlikely to occur. Therefore, the onium salt contained in the RuO₄ gas generation inhibitor of the present embodiment contains a bromine-containing ion.

In the RuO₄ gas generation inhibitor of the present embodiment, the concentration of the bromine-containing ion is 0.1 μmol/L or more and less than 0.001 mol/L. When the concentration of the bromine-containing ion is less than 0.1 μmol/L, the interaction of the bromine-containing ion with a ruthenium surface is weakened, and this leads to a reduction in the effect of keeping RuO₄⁻ and the like, which are anions, away from the ruthenium surface, as a result of which RuO₂ particles are likely to be formed. Further, since the concentration of the onium ion, which is a counter cation of the bromine-containing ion, is reduced in the ruthenium treatment liquid, the effect of inhibiting the generation of RuO₄ gas is reduced as well. Meanwhile, when the concentration of the bromine-containing ion is 0.001 mol/L or more, RuO₄ and the bromine-containing ion react with each other, and this may cause RuO₄ to precipitate in the form of RuO₂ particles. Precipitation of RuO₂ particles is not preferred since it not only causes a reduction in the yield in semiconductor fabrication, but also markedly deteriorates the flatness of ruthenium surface. Therefore, in the RuO₄ gas generation inhibitor of the present embodiment, the concentration of the bromine-containing ion is preferably 0.5 μmol/L or more and less than 0.001 mol/L, more preferably 1 μmol/L or more and less than 0.001 mol/L. The concentration of the bromine-containing ion can be adjusted to be in the above-described concentration range also in a liquid obtained by mixing the RuO₄ gas generation inhibitor and the ruthenium treatment liquid. When an onium salt is added, the onium salt can be of a single kind, or a combination of two or more kinds. Even when the RuO₄ gas generation inhibitor contains two or more kinds of onium salts, the generation of RuO₄ gas can be effectively inhibited as long as a total concentration of bromine-containing ion in the RuO₄ gas generation inhibitor is in the above-described concentration range. Further, the above-described concentration range is applicable to both of the below-described onium salts represented by Formulae (1) and (2).

By incorporating the above-described onium salt, the generation of RuO₄ gas from the ruthenium treatment liquid is inhibited. In other words. RuO₄⁻ and the like generated by dissolution of ruthenium are trapped in the ruthenium treatment liquid by electrostatic interaction with onium ions. The trapped RuO₄⁻ and the like relatively stably exist as ion pairs in the treatment liquid, and thus do not easily change into RuO₄. Consequently, not only the generation of RuO₄ gas is inhibited, but also the formation of RuO₂ particles is inhibited.

Specific examples of the onium ion contained in the onium salt include a tetrapropylammonium ion, a tetrabutylammonium ion, a tetrapentylammonium ion, a tetrahexylammonium ion, a 1-butyl-2,3-dimethylimidazolium ion, a 1-hexyl-3-methylimidazolium ion, a 1-methyl-3-n-octylimidazolium ion, a 1-butyl-1-methylpyrrolidinium ion, a 1-ethyl-1-methylpyrrolidinium ion, a 1-butyl-1-methylpiperidinium ion, a 5-azoniaspiro[4,4]nonane ion, a 1-methylpyridinium ion, a 1-ethylpyridinium ion, a 1-propylpyridinium ion, a hexamethonium ion, and a decamethonium ion, and the onium salt is composed of any of these onium ions and a bromine-containing ion, such as a bromite ion, a bromate ion, a perbromate ion, a hypobromite ion, or a bromide ion. Needless to say, an onium salt that can be contained in the RuO₄ gas generation inhibitor of the present embodiment is not limited to the above-described onium salt.

As an onium salt having an effect of inhibiting the generation of RuO₄ gas, one represented by the following Formula (1) or (2) is preferred.

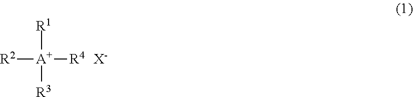

(wherein, A represents nitrogen or phosphorus; R¹, R², R³, and R⁴ each independently represent an alkyl group having carbon number of 1 to 25, an allyl group, an aralkyl group containing an alkyl group having carbon number of 1 to 25, or an aryl group, provided that when R¹, R², R³, and R⁴ are alkyl groups, at least one of the alkyl groups of R¹, R², R³, and R⁴ has carbon number of 3 or more; in a ring of an aryl group in the aralkyl group and a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom; and X⁻ represents a bromine-containing ion)

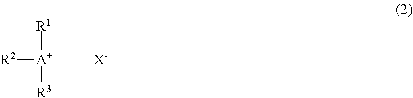

(wherein, A represents sulfur; R¹, R², and R³ each independently represent an alkyl group having carbon number of 1 to 25, an allyl group, an aralkyl group containing an alkyl group having carbon number of 1 to 25, or an aryl group, provided that when R¹, R², and R³ are alkyl groups, at least one of the alkyl groups of R¹, R², and R³ has carbon number of 3 or more; in a ring of an aryl group in the aralkyl group and a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom; and X⁻ represents a bromine-containing ion)

As the alkyl groups of R¹, R², R³, and R⁴ in Formula (1) or (2), independently, any alkyl group can be used with no particular limitation as long as it has carbon number of 1 to 25. When the carbon number is large, specifically when the carbon number is, for example, 3 or more, the onium ion more strongly interacts with RuO₄⁻ and the like, so that the generation of RuO₄ gas is more likely to be inhibited. On the other hand, since a larger carbon number makes the onium ion bulkier, the ion pairs generated by electrostatic interaction of the onium ion with RuO₄⁻ and the like are less likely to dissolve in the ruthenium treatment liquid, resulting in the generation of a precipitate. This precipitate gives particles to cause a reduction in the yield of a semiconductor element. In addition, the larger the carbon number, the lower is the solubility of the onium salt in the ruthenium treatment liquid and the more likely are bubbles to be formed in the treatment liquid. When the solubility is high, a greater amount of the onium salt can be dissolved in the treatment liquid, so that the effect of inhibiting the generation of RuO₄ gas is enhanced. Conversely, when the carbon number is small, since the interaction of the onium ion with RuO₄⁻ and the like is weak, the effect of inhibiting the generation of RuO₄ gas is reduced. Accordingly, the carbon numbers of the alkyl groups in Formula (1) or (2) are independently preferably 1 to 25, more preferably 2 to 10, most preferably 3 to 6. However, when R¹, R², R³, and R⁴ in Formula (1) are alkyl groups, at least one of these alkyl groups of R¹, R², R³, and R⁴ can have carbon number of 2 or more and, when R¹, R², and R³ in Formula (2) are alkyl groups, at least one of these alkyl groups of R¹, R², and R³ can have carbon number of 2 or more. An onium salt containing alkyl groups having such carbon number can be preferably used as a RuO₄ gas generation inhibitor since it is capable of inhibiting the generation of RuO₄ gas through interaction with RuO₄⁻ and the like and thus unlikely to generate a precipitate.

The aryl groups of R¹, R², R³, and R⁴ in Formula (1) or (2) independently encompass not only aromatic hydrocarbons but also heteroatom-containing heteroaryls and are not particularly limited; however, the aryl groups are each preferably a phenyl group or a naphthyl group. Examples of the heteroatom include nitrogen, oxygen, sulfur, phosphorus, chlorine, bromine, and iodine.

The quaternary and tertiary onium salts represented by Formulae (1) and (2) are each a salt containing an ammonium ion, a phosphonium ion, or a sulfonium ion that can stably exist in the RuO₄ gas generation inhibitor or the ruthenium treatment liquid. Generally, the alkyl chain length of these ions can be easily controlled, and it is also easy to introduce thereto an allyl group or an aryl group. This makes it possible to control the size, symmetry, hydrophilicity, hydrophobicity, stability, solubility, charge density, surfactant performance, and the like of the ions, and salts containing any of the ions can also be controlled in the same manner. Such salts can be used as the onium salts represented by Formulae (1) and (2) of the present embodiment. Examples of the ammonium ion contained in the quaternary and tertiary onium salts represented by Formulae (1) and (2) include the same ones as those included in the quaternary onium bromide described for a third embodiment.

The quaternary onium salt represented by Formula (1) that is contained the RuO₄ gas generation inhibitor of the present embodiment is preferably an ammonium salt since it is highly stable and a high-purity product thereof is readily available industrially and inexpensive. Among ammonium salts, the onium salt is preferably a tetraalkylammonium salt since it has particularly excellent stability and can be easily synthesized. Specific examples thereof include salts containing a tetraethylammonium ion, a tetrapropylammonium ion, a tetrabutylammonium ion, a tetrapentylammonium ion, or a tetrahexylammonium ion. An inhibitor containing such an onium salt can inhibit particularly the generation of RuO₄ gas and RuO₂ particles in a treatment of ruthenium.

The RuO₄ gas generation inhibitor of the present embodiment can further contain an oxidizing agent. This oxidizing agent refers to an oxidizing agent which has the ability to substantially dissolve ruthenium contained in a semiconductor wafer. As the oxidizing agent, any oxidizing agent known to be capable of dissolving ruthenium can be used with no particular limitation. Examples of the oxidizing agent include, but not limited to: a halogen oxyacid, permanganic acid, salts of these acids, hydrogen peroxide, ozone, and cerium (IV) salts. The oxidizing agent is preferably a halogen oxyacid or ozone, more preferably a halogen oxyacid. It is noted here that the halogen oxyacid refers to hypochlorous acid, chlorous acid, chloric acid, perchloric acid, hypobromous acid, bromous acid, bromic acid, perbromic acid, hypoiodous acid, iodous acid, iodic acid, metaperiodic acid, orthoperiodic acid, or an ion of any of these acids. Among halogen oxyacids, the oxidizing agent is preferably hypochlorous acid, chlorous acid, perchloric acid, hypobromous acid, bromic acid, perbromic acid, metaperiodic acid, orthoperiodic acid, or an ion of any of these acids; more preferably hypochlorous acid, hypobromous acid, metaperiodic acid, orthoperiodic acid, or an ion of any of these acids; still more preferably hypochlorous acid, hypobromous acid, or an ion of either of these acids. The oxidizing agent can dissolve ruthenium contained in a wafer; therefore, the RuO₄ gas generation inhibitor that contains the oxidizing agent and the onium salt can dissolve ruthenium and inhibit the generation of RuO₄ gas at the same time. In addition, by incorporating the oxidizing agent, not only dissolution of ruthenium but also re-dissolution of precipitated RuO₂ particles are facilitated. Accordingly, the RuO₄ gas generation inhibitor that contains the onium salt and the oxidizing agent can efficiently treat a ruthenium-containing wafer while inhibiting the generation of RuO₄ gas and RuO₂ particles.

Among halogen oxyacids, a hypochlorite ion has a high redox potential and, therefore, ruthenium dissolved in a hypochlorous acid-containing solution can relatively stably exist as RuO₄ and the like. Accordingly, when the RuO₄ gas generation inhibitor of the present embodiment further contains a hypochlorite ion, the interaction of RuO₄ and the like with the onium ion is more likely to be maintained, as a result of which the effect of inhibiting the generation of RuO₄ gas is enhanced. In addition, formation of RuO₂ particles is inhibited by the inhibition of the generation of RuO₄ gas. A hypochlorite ion can be preferably used as the oxidizing agent that can be further contained in the RuO₄ gas generation inhibitor of the present embodiment, since a high-purity product thereof suitable for semiconductor fabrication can be relatively easily obtained. The concentration of the hypochlorite ion that can be contained in the RuO₄ gas generation inhibitor is preferably 500 ppb by mass or more and 20.0% by mass or less. By using a ruthenium treatment liquid containing the RuO₄ gas generation inhibitor of the present embodiment that has a hypochlorite ion concentration in the above-described range, ruthenium can be treated while inhibiting the generation of RuO₄ gas and RuO₂ particles.

### (pH of RuO₄ Gas Generation Inhibitor)

The RuO₄ gas generation inhibitor of the present embodiment preferably has a pH of 8 or higher and 14 or lower at 25° C. When the pH is lower than 8, dissolution of ruthenium is likely to occur via RuO₂ and Ru(OH); rather than an anion such as RuO₄⁻, and the gas generation-inhibiting effect exerted by the onium salt is thus likely to be reduced. RuO₂ serves as a source of particles and, at a pH of lower than 8, RuO₂ also causes a problem that the amount of RuO₄ gas generation is increased. Meanwhile, when the pH is higher than 14, redissolution of RuO₂ is unlikely to occur, and generation of RuO₂ particles thus becomes a problem. Therefore, in order to allow the inhibitor to sufficiently exert its RuO₄ gas generation inhibitory capacity, the pH of the inhibitor is preferably 8 or higher and 14 or lower, more preferably 12 or higher and 13 or lower. In this pH range, dissolved ruthenium exists in the form of an anion such as RuO₄⁻ or RuO₄²⁻ and is thus likely to form an ion pair with the onium ion contained in the inhibitor, so that the generation of RuO₄ gas can be effectively inhibited.

### (Other Components of RuO₄ Gas Generation Inhibitor)

In the RuO₄ gas generation inhibitor of the present embodiment, other additives that are conventionally used in semiconductor treatment liquids can be incorporated within a range that does not hinder the object of the present invention. As such other additives, for example, an acid, a metal corrosion inhibitor, an aqueous organic solvent, a fluorine compound, an oxidizing agent, a reducing agent, a complexing agent, a chelating agent, a surfactant, an antifoaming agent, a pH modifier, and a stabilizing agent can be added. These additives can be added singly, or in combination of two or more thereof.

### (Method of Inhibiting RuO₄ Gas Generation and Halogen Oxyacid)

A method of inhibiting the generation of RuO₄ gas includes the step of adding the RuO₄ gas generation inhibitor of the present embodiment to a ruthenium treatment liquid. Specifically, the generation of RuO₄ gas can be inhibited by adding the RuO₄ gas generation inhibitor of the present embodiment to a ruthenium treatment liquid used in, for example, the etching step, the residue removal step, the washing step, or the CMP step in a semiconductor fabrication process. Further, by using the RuO₄ gas generation inhibitor of the present embodiment, the generation of RuO₄ gas can be inhibited also at the time of washing ruthenium adhering to the chamber inner wall, the piping and the like of each apparatus used in these semiconductor fabrication steps. For example, in the maintenance of an apparatus that forms Ru by physical vapor deposition (PVD), chemical vapor deposition (CVD), atomic layer deposition (ALD) or the like, the generation of RuO₄ gas during washing can be inhibited by adding the RuO₄ gas generation inhibitor to a washing liquid used for removing Ru adhering to a chamber, a piping and the like. According to this method, the generation of RuO₄ gas can be inhibited by the above-described mechanism.

For example, in the ruthenium wiring formation step, the RuO₄ gas generation inhibitor of the present embodiment is used in the following manner. First, a substrate made of a semiconductor (e.g., Si) is prepared. This substrate is oxidized to form a silicon oxide film thereon. Subsequently, an interlayer insulating film composed of a low-dielectric-constant (Low-k) film is formed, and via-holes are formed thereon at prescribed intervals. Thereafter, ruthenium is embedded into the via-holes by thermal CVD to further form a ruthenium film. This ruthenium film is etched with a ruthenium treatment liquid to which the RuO₄ gas generation inhibitor is added, whereby the ruthenium film is planarized while the generation of RuO₄ gas is inhibited. As a result, a highly reliable ruthenium wiring in which the generation of RuO₂ particles is inhibited can be formed. Further, the ruthenium treatment liquid to which the RuO₄ gas generation inhibitor is added can also be used for removing ruthenium adhering to the bevel of a semiconductor wafer.

The RuO₄ gas generation inhibitor of the present embodiment can inhibit the generation of RuO₄ gas not only in a ruthenium treatment liquid but also in a liquid obtained after a treatment of ruthenium (hereinafter, referred to as “ruthenium-containing liquid”). The term “ruthenium-containing liquid” used herein means a liquid that contains ruthenium even in a small amount. The ruthenium contained in a ruthenium-containing liquid is not limited to metal ruthenium as long as it contains elemental ruthenium, and examples thereof include Ru, RuO₄⁻, RuO₄²⁻ RuO₄, RuO₂, and a ruthenium complex. Examples of a ruthenium-containing liquid include: a liquid waste generated from the above-described semiconductor fabrication process, chamber washing or the like; and a treatment liquid that has captured RuO₄ gas and remains in an exhaust gas treatment equipment (scrubber). When even a trace amount of ruthenium is contained in such a ruthenium-containing liquid, RuO₂ particles are generated via RuO₄ gas, as a result of which a tank and a piping are contaminated, and deterioration of equipment is facilitated by the oxidizing effect of the particles. In addition, RuO₄ gas generated from a ruthenium-containing liquid is highly toxic to the human body even at a low concentration. In this manner, a ruthenium-containing liquid has various adverse effects on equipment and human body; therefore, it is necessary to treat such a ruthenium-containing liquid safely and promptly while inhibiting the generation of RuO₄ gas. By adding the RuO₄ gas generation inhibitor of the present embodiment to a ruthenium-containing liquid, not only the generation of RuO₄ gas can be inhibited and the ruthenium-containing liquid can be safely treated, but also contamination and deterioration of a tank and a piping of an equipment can be reduced.

The amount of the RuO₄ gas generation inhibitor of the present embodiment to be added to a ruthenium treatment liquid or a ruthenium-containing liquid can be determined taking into consideration the amount of ruthenium existing in the liquid. The amount of the RuO₄ gas generation inhibitor of the present embodiment to be added is not particularly limited; however, for example, when the amount of ruthenium existing in a ruthenium treatment liquid or a ruthenium-containing liquid is taken as 1, the RuO₄ gas generation inhibitor is added in an amount of preferably 10 to 500,000, more preferably 100 to 100,000, still more preferably 1,000 to 50,000, in terms of weight ratio.

The pH of a mixture of the RuO₄ gas generation inhibitor and a ruthenium treatment liquid or a ruthenium-containing liquid at 25° C. is preferably, for example, 7 to 14. For the adjustment of the pH of this mixture, any of the above-exemplified acids, alkalis, pH buffers, and/or solvents can be added.

A third embodiment of the present invention is a method of producing a halogen oxyacid by allowing a bromine salt, an organic alkali, and a halogen to react with each other to obtain the halogen oxyacid.

The production method of this embodiment is characterized in that a halogen is added to a solution containing a bromine salt and an organic alkali. A halogen added to a solution containing an organic alkali reacts with the organic alkali to generate a halogen oxyacid and a halide. As a result, a halide-containing halogen oxyacid solution can be obtained. In the present embodiment, unless otherwise specified, “halogen oxyacid” refers to a hypohalous acid, a halous acid, a halogen acid, a perhalous acid, or an ion of any of these acids. The resulting halogen oxyacid can contain any one of, or two or more of a hypohalous acid, a halous acid, a halogen acid, and a perhalous acid.

### (Halogen)

In the production method of the present embodiment, “halogen” refers to fluorine, chlorine, bromine, or iodine. Any of these halogens can be added in the form of a gas or a halogen-containing solution, to a solution containing a bromine salt and an organic alkali. Regardless of whether the halogen is in the form of a halogen gas or a halogen-containing solution, the halogen reacts with the bromine salt and the organic alkali to yield a halogen oxyacid, so that the halogen oxyacid of the present embodiment can be obtained; however, it is preferred to use a halogen gas since it is easy to handle and a high-purity product thereof is readily available industrially. Among halogen gases, chlorine gas can be particularly preferably used since a semiconductor-grade high-purity product thereof can be obtained relatively inexpensively and, as described below, it can easily oxidize a bromine salt directly or indirectly to yield a halogen oxyacid. A rate at which a halogen gas is supplied is not particularly limited, and can be determined as appropriate taking into consideration the amount of the halogen to be supplied and the reaction time. Further, the halogen gas to be used can be mixed with an inert gas, such as nitrogen or argon.

For example, when the halogen is chlorine, chlorine is added to and allowed to react with a solution containing a bromine salt and an organic alkali, whereby a halogen oxyacid which contains the bromine salt and at least one halogen oxyacid selected from hypochlorous acid, chlorous acid, chloric acid, and perchloric acid, along with a chloride can be obtained. Further, when the halogen is bromine, bromine is added to and allowed to react with a solution containing a bromine salt and an organic alkali, whereby a halogen oxyacid which contains the bromine salt and at least one halogen oxyacid selected from hypobromous acid, bromous acid, bromic acid, and perbromic acid, along with a bromide can be obtained. Moreover, when the halogen is iodine, iodine is added to and allowed to react with a solution containing a bromine salt and an organic alkali, whereby a halogen oxyacid which the bromine salt and at least one halogen oxyacid selected from hypoiodous acid, iodous acid, iodic acid, and periodic acid, along with an iodide can be obtained.

### (Organic Alkali)

In the production method of the present embodiment, “organic alkali” refers to an organic alkali composed of an organic cation and a hydroxide ion. Such an organic alkali does not contain any metal that causes a problem in semiconductor fabrication. Therefore, by using such an organic alkali, the metal content in the resulting halogen oxyacid can be reduced, allowing the halogen oxyacid to be preferably used in a semiconductor fabrication process. The organic cation is, for example, an onium ion. An onium ion is a polyatomic cation formed by addition of excess protons (hydrogen cations) to a monoatomic anion. Specific examples of the onium ion include cations such as an imidazolium ion, a pyrrolidinium ion, a pyridinium ion, a piperidinium ion, an ammonium ion, a phosphonium ion, a fluoronium ion, a chloronium ion, a bromonium ion, an iodonium ion, an oxonium ion, a sulfonium ion, a selenonium ion, a telluronium ion, an arsonium ion, a stibonium ion, and a bismuthonium ion. Thereamong, an ammonium ion, a phosphonium ion, and a sulfonium ion are preferred as the organic cation contained in the organic alkali of the present embodiment since these onium ions stably exist in an alkaline solution, and the carbon chains and functional groups contained in these onium ions can be easily modified, so that the solubility, the bulkiness, and the charge density can be easily controlled. The onium ion is more preferably an ammonium ion since it can be industrially mass-produced at a low cost. The ammonium ion is, for example, a tetraalkylammonium ion, preferred examples of which include a tetramethylammonium ion, an ethyltrimethylammonium ion, a tetraethylammonium ion, a tetrapropylammonium ion, and a tetrabutylammonium ion. An organic alkali containing an onium ion and a hydroxide ion, namely onium hydroxide, can be preferably used as the organic alkali of the present embodiment. In addition, an organic alkali containing an ammonium ion (NH₄⁺) or 2-hydroxyethyltrimethylammonium as an organic cation can also be preferably used as the organic alkali of the present embodiment.

Considering the stability of the halogen oxyacid, the pH of the halogen oxyacid is preferably 8 or higher and lower than 14. The concentration of the organic alkali used for the production of a halogen oxyacid is not particularly limited as long as the pH of the resulting halogen oxyacid is in the above-described range, and it can be determined taking into consideration the type of the organic alkali to be used as well as the type and the amount of the halogen to be added. The concentration of the organic alkali is, for example, 0.0001% by mass or more and 30% by mass or less.

### (Bromine Salt)

In the present embodiment, “bromine salt” refers to a salt that contains a bromine atom, such as a hypobromite, a bromite, a bromate, a perbromate, or a bromide. Examples of the bromide include hydrogen bromide, lithium bromide, sodium bromide, potassium bromide, rubidium bromide, cesium bromide, ammonium bromide, and onium bromides. The term “onium bromide” used herein refers to a compound formed of the above-described onium ion and a bromide ion. A compound that generates hypobromous acid or a hypobromite ion in the treatment liquid can also be preferably used as a bromine-containing compound. Examples of such a compound include, but not limited to: bromohydantoins, bromoisocyanuric acids, bromosulfamic acids, and bromochloramines. More specific examples of the compound include 1-bromo-3-chloro-5,5-dimethylhydantoin, 1,3-dibromo-5,5-dimethylhydantoin, and tribromoisocyanuric acid.

The bromine salt can be added to an organic alkali-containing solution in the form of a bromine salt, in the form of a solution containing the bromine salt, or in the form of bromine gas. Because of the ease of handling in the halogen oxyacid production process, the bromine salt is preferably mixed with an organic alkali-containing solution in the form of a bromide or a bromide-containing solution. The bromine salt to be added to an organic alkali-containing solution can be of a single kind, or a combination of two or more kinds. Alternatively, depending on the circumstances of the production process, the organic alkali can be added to a solution containing the bromine salt. Further, the bromine salt and the organic alkali can be simultaneously added to an appropriate solvent to prepare a solution containing the bromine salt and the organic alkali. In any of these cases, a solution containing the bromine salt and the organic alkali can be obtained.

In the semiconductor fabrication, contamination by a metal or a metal ion causes a reduction in the yield; therefore, the bromine salt desirably contains no metal. Bromine gas, or an onium bromide among bromine salts, does not substantially contain any metal and thus can be preferably used as the bromine salt of the present embodiment. Particularly, a quaternary onium bromide or a tertiary onium bromide among onium bromides, or hydrogen bromide is more preferred as the bromine salt of the present embodiment because of industrial availability and ease of handling.

A quaternary onium bromide is a bromine salt containing an ammonium ion or a phosphonium ion that can stably exist in a solution containing a bromine salt and an organic alkali. Examples of the quaternary onium bromide include tetramethylammonium bromide, ethyltrimethylammonium bromide, tetraethylammonium bromide, tetrapropylammonium bromide, tetrabutylammonium bromide, tetrapentylammonium bromide, tetrahexylammonium bromide, methyltriethylammonium bromide, diethyldimethylammonium bromide, trimethylpropylammonium bromide, butyltrimethylammonium bromide, trimethylnonylammonium bromide, decyltrimethylammonium bromide, tetradecyltrimethylammonium bromide, hexadecyltrimethylammonium bromide, trimethylstearylammonium bromide, decamethonium bromide, phenyltrimethylammonium bromide, benzyltrimethylammonium bromide, dimethylpyrrolidinium bromide, dimethylpiperidinium bromide, 1-butyl-3-methylimidazolium bromide, and 1-butyl-3-methylpyridinium bromide. Further, a compound in which a proton is added to a tertiary amine, a secondary amine, or a primary amine can be used as well. Examples thereof include methylamine hydrobromide, dimethylamine hydrobromide, ethylamine hydrobromide, diethylamine hydrobromide, triethylamine hydrobromide, 2-bromoethylamine hydrobromide, 2-bromoethyldiethylamine hydrobromide, ethylenediamine dihydrobromide, propylamine hydrobromide, butylamine hydrobromide, tert-butylamine hydrobromide, neopentylamine hydrobromide, 3-bromo-1-propylamine hydrobromide, dodecylamine hydrobromide, cyclohexaneamine hydrobromide, and benzylamine hydrobromide.

Examples of a quaternary phosphonium bromide include tetramethylphosphonium bromide, tetraethylphosphonium bromide, tetrapropylphosphonium bromide, tetrabutylphosphonium bromide, tetraphenylphosphonium bromide, methyltriphenylphosphonium bromide, phenyltrimethylphosphonium bromide, and methoxycarbonylmethyltriphenyl)phosphonium bromide. A tertiary onium bromide is a bromine salt containing a sulfonium ion that can stably exist in the treatment liquid. Examples of the tertiary sulfonium bromide include trimethylsulfonium bromide, triethylsulfonium bromide, tripropylsulfonium bromide, tributylsulfonium bromide, triphenylsulfonium bromide, and (2-carboxyethyl)dimethylsulfonium bromide. Among the above-described salts, a quaternary onium bromide, which is a bromine salt containing an ammonium ion, is preferred since it is highly stable and a high-purity product thereof is readily available industrially and inexpensive.

The quaternary onium salt is preferably a tetraalkylammonium bromide since it has particularly excellent stability and can be easily synthesized. In the tetraalkylammonium bromide, the carbon number of each alkyl group is not particularly limited, and the four alkyl groups can have the same carbon number, or different carbon numbers. Examples of such an alkylammonium bromide that can be preferably used include tetraalkylammonium bromides having carbon number of 1 to 20 per alkyl group. Thereamong, a tetraalkylammonium bromide having a smaller carbon number in its alkyl groups can be more preferably used since it contains more bromine atoms per weight. Examples of such a tetraalkylammonium bromide include tetramethylammonium bromide, ethyltrimethylammonium bromide, tetraethylammonium bromide, tetrapropylammonium bromide, tetrabutylammonium bromide, tetrapentylammonium bromide, and tetrahexylammonium bromide, among which tetramethylammonium bromide, tetraethylammonium bromide, tetrapropylammonium bromide, and tetrabutylammonium bromide are preferred, and tetramethylammonium bromide is most preferred. The solution containing the bromine salt and the organic alkali can contain a single bromine-containing compound, or plural bromine-containing compounds.

The tetraalkylammonium bromide used in the present embodiment can be a commercially available tetraalkylammonium bromide, or can be a tetraalkylammonium bromide produced from a tetraalkylammonium and a bromide ion. As a method of producing the tetraalkylammonium bromide, it only needs to mix a tetraalkylammonium hydroxide-containing aqueous solution with a bromide ion-containing aqueous solution, or a bromine-containing gas that yields bromine ions when dissolved in water.

Examples of the tetraalkylammonium hydroxide used for producing the tetraalkylammonium bromide include tetramethylammonium hydroxide, ethyltrimethylammonium hydroxide, tetraethylammonium hydroxide, tetrapropylammonium hydroxide, and tetrabutylammonium hydroxide. Thereamong, the tetraalkylammonium hydroxide is more preferably tetramethylammonium hydroxide or ethyltrimethylammonium hydroxide since it contains a large amount of hydroxide ion per unit weight and a high-purity product thereof is readily available.

Examples of a bromine ion source that generates the bromide ion used for producing the tetraalkylammonium bromide include hydrogen bromide, lithium bromide, sodium bromide, potassium bromide, rubidium bromide, cesium bromide, and ammonium bromide. Thereamong, hydrogen bromide is preferred since it contains substantially no metal and is easy to obtain industrially, and a high-purity product thereof is readily available.

### (Solvent)

A solvent of the solution containing the bromine salt and the organic alkali is not particularly limited, and water or an organic solvent can be used. Naturally, when water is used as the solvent of the solution containing the bromine salt and the organic alkali, the solvent of the resulting halogen oxyacid is also water.

As the solvent, water is most preferably used, and this water is preferably water from which metal ions, organic impurities, particles and the like have been removed by distillation, ion exchange, filtration, or various adsorption treatments, and the water is particularly preferably pure water or ultrapure water. Such water can be obtained by a known method widely utilized in the semiconductor fabrication.

Further, as the solvent, water and an organic solvent can be used in combination as well. The use of water and an organic solvent in combination allows oxidation of a transition metal to proceed relatively slowly, so that oxidation of wiring and the like of a circuit forming part can be inhibited. When water and an organic solvent are used in combination, the mass ratio of water to the organic solvent (water/organic solvent) can be about 60/40 to 99.9/0.1.

### (Reaction of Bromine Salt, Organic Alkali and Halogen)

The method of producing a halogen oxyacid according to the third embodiment is a method of producing a halogen oxyacid by a reaction of a bromine salt, an organic alkali and a halogen. A halogen added to a solution containing a bromine salt and an organic alkali is quickly dissolved in the solution and reacts with the organic alkali to generate a hypohalous acid and a halide. This hypohalous acid further reacts with a bromide ion, a bromite ion, a hypobromite ion, a bromate ion or a perbromate ion that is contained in the bromite salt, or with a bromine molecule generated from the bromine salt, to yield a new halogen oxyacid. In this process, the reaction between the hypohalous acid and the ion or the bromine molecule may be a redox reaction, a disproportionation reaction or a radical reaction, as long as it yields a new halogen oxyacid when the halogen is added to the solution containing the bromine salt and the organic alkali.

For more concrete description, one example of a reaction of a bromine salt, an organic alkali and a halogen, where the bromine salt is tetramethylammonium bromide, the organic alkali is tetramethylammonium hydroxide and the halogen is chlorine, is described as follows. When chlorine gas is blown into an aqueous solution that contains tetramethylammonium bromide and tetramethylammonium hydroxide, tetramethylammonium hydroxide and chlorine react with each other to generate hypochlorous acid and a chloride. This hypochlorous acid partially reacts with the bromide ion of tetramethylammonium bromide contained in the aqueous solution and thereby directly oxidizes the bromide ion to generate hypobromous acid. As a result, an aqueous solution that contains hypochlorous acid, hypobromous acid, a chloride (tetramethylammonium chloride), unreacted tetramethylammonium bromide and tetramethylammonium hydroxide is obtained. In other words, an aqueous solution containing two kinds of halogen oxyacids (hypochlorous acid and hypobromous acid) is obtained. Alternatively, when the number of moles of chlorine molecule is less than that of tetramethylammonium bromide in the solution containing the bromine salt and the organic alkali, an aqueous solution that contains hypobromous acid, a chloride (tetramethylammonium chloride), unreacted tetramethylammonium bromide and tetramethylammonium hydroxide is obtained.

As another concrete example, a reaction of a bromine salt, an organic alkali and a halogen, where the bromine salt is tetramethylammonium hypobromite, the organic alkali is tetramethylammonium hydroxide and the halogen is chlorine, is described as follows. When bromine gas is blown into an aqueous solution that contains tetramethylammonium hypobromite and tetramethylammonium hydroxide, tetramethylammonium hydroxide and chlorine react with each other to generate hypochlorous acid and a chloride. This hypochlorous acid partially reacts with hypobromous acid of tetramethylammonium hypobromite contained in the aqueous solution, and thereby converted into chlorous acid and bromous acid. As a result, an aqueous solution that contains hypochlorous acid, chlorous acid, bromous acid, unreacted tetramethylammonium hypobromite and tetramethylammonium hydroxide is obtained. In other words, an aqueous solution containing four kinds of halogen oxyacids (hypochlorous acid, chlorous acid, bromous acid, and hypobromous acid) is obtained.

A semiconductor treatment liquid containing a halogen oxyacid produced by the production method of the present embodiment not only has excellent chemical liquid stability, but also is capable of stably etching a transition metal at a sufficient etching rate and maintaining the flatness of a transition metal surface after the etching. Especially, when the treatment liquid contains 0.1 μmol/L or more and less than 0.001 mol/L of a hypobromite ion, the treatment liquid not only has particularly excellent chemical liquid stability, but also, as described above, is capable of etching a transition metal at a sufficient etching rate and maintaining the flatness of a transition metal surface after the etching. Therefore, as described above for the first embodiment, such a treatment liquid can be preferably as a treatment liquid of a transition metal-containing semiconductor wafer.

In the above-described manner, when a treatment liquid is produced using an onium hydroxide as an organic alkali, bromine as a halogen and an onium bromide as a bromine salt, a treatment liquid that contains a hypobromite ion and a bromine-containing ion is obtained by a reaction between bromine and the onium hydroxide. Further, when a treatment liquid is produced using an onium hydroxide as an organic alkali, chlorine as a halogen, and an onium bromide as a bromine salt, a hypochlorite ion and a chloride ion are generated in the resulting treatment liquid by a reaction between chlorine and the onium hydroxide, and this hypochlorite ion further reacts with the bromine salt. As a result, a treatment liquid that contains a hypobromite ion and a bromine-containing ion is obtained. The thus obtained treatment liquids can be used not only as a semiconductor wafer treatment liquid, but also as a RuO₄ gas generation inhibitor. Examples of the bromine-containing ion include those exemplified above for the second embodiment.

The concentration of the halogen oxyacid produced by the production method of the present embodiment is not particularly limited; however, for example, the concentration of a hypochlorite ion or a bromine-containing ion is preferably 0.1 μmol/L or more and less than 0.001 mol/L. When the concentration of the halogen oxyacid is in this range, the halogen oxyacid can be particularly suitably used as the above-described semiconductor wafer treatment liquid and/or RuO₄ gas generation inhibitor. In cases where the concentration of the halogen oxyacid produced by the production method of the present embodiment is lower than the above-described concentration range, the concentration of the halogen oxyacid can be increased by, for example, increasing the supply amount of the halogen reacting with the organic alkali, or by adding a halogen oxyacid salt. In cases where the concentration of the halogen oxyacid is higher than the above-described concentration range, for example, the halogen oxyacid can be diluted with an appropriate solvent. In order to perform etching of a transition metal at a sufficient rate in a stable manner and to maintain the flatness of the metal surface after the etching, the concentration of the halogen oxyacid is preferably 0.1 μmol/L or more and less than 0.001 mol/L, more preferably 1 μmol/L or more and less than 0.001 mol/L, still more preferably 10 μmol/L or more and less than 0.001 mol/L, most preferably 50 mol/L or more and less than 0.001 mol/L.

The halogen oxyacid can be contained singly, or in combination of two or more kinds thereof. When plural kinds of halogen oxyacids are contained, the concentration of each halogen oxyacid is preferably 0.1 μmol/L or more and less than 0.001 mol/L.

### (Other Additives)

In the halogen oxyacid produced by the method of producing a halogen oxyacid according to the third embodiment, as desired, other additives that are conventionally used in semiconductor treatment liquids can be incorporated within a range that does not hinder the object of the present invention. As such other additives, for example, an acid, a metal corrosion inhibitor, an aqueous organic solvent, a fluorine compound, an oxidizing agent, a reducing agent, a complexing agent, a chelating agent, a surfactant, an antifoaming agent, a pH modifier, and a stabilizing agent can be added. These additives can be added singly, or in combination of two or more thereof.

In the halogen oxyacid of the present embodiment, an alkali metal ion, an alkaline earth metal ion and the like, which are derived from the above-described additives or added depending on the circumstances in the production of the halogen oxyacid, may be contained. For example, the halogen oxyacid may contain a sodium ion, a potassium ion, or a calcium ion. However, such alkali metal ion, alkaline earth metal ion and the like, if remain on a semiconductor wafer, have adverse effects (e.g., a reduction in the yield of the semiconductor wafer) on a semiconductor element; therefore, the smaller the amount thereof, the more preferred it is and, in practice, it is preferred that such ions and the like be substantially not contained. Accordingly, for example, the pH modifier is preferably an organic alkali such as ammonia, amine, choline, or tetraalkylammonium hydroxide, rather than an alkali metal hydroxide such as sodium hydroxide, or an alkaline earth metal hydroxide.

Specifically, a total amount of an alkali metal ion and an alkaline earth metal ion is preferably 1% by mass or less, more preferably 0.7% by mass or less, still more preferably 0.3% by mass or less, particularly preferably 10 ppm or less, most preferably 500 ppb or less.

In the production of a halogen oxyacid by the production method according to the present embodiment, any of the conditions and measures that are described above for the semiconductor wafer treatment liquid and the RuO₄ gas generation inhibitor can be selected and employed as appropriate. For example, the above-described conditions and measures can be suitably used for inhibiting dissolution of carbon dioxide, contamination with amines, contamination with metals, decomposition caused by light, and the like.

As described above, the method of producing a halogen oxyacid according to the present embodiment is a method by which a halogen oxyacid, particularly a semiconductor wafer treatment liquid containing a hypobromite ion and a bromine-containing ion, can be obtained in a simple and efficient manner. In addition, the method of producing a halogen oxyacid according to the present embodiment is a method which enables to inhibit contamination with a metal that poses a problem in semiconductor fabrication, such as sodium, potassium, or calcium and, according this production method, the amount of a contaminant metal can be greatly reduced as compared to a method of producing a halogen oxyacid based on an ion exchange method using an aqueous solution of a sodium salt, a potassium salt, a calcium salt or the like of a hypohalous acid as a raw material. Moreover, in this production method, since production can be carried out continuously without the need for periodic regeneration and the like of an ion exchange resin required for the ion exchange method, the productivity of a treatment liquid is high, and the production cost can be reduced. Therefore, the method of producing a halogen oxyacid according to the present embodiment is particularly preferably employed as a method of producing a halogen oxyacid used as a semiconductor wafer treatment liquid and/or a RuO₄ gas generation inhibitor.

### EXAMPLES

The present invention will now be described more concretely by way of Examples; however, the present invention is not limited to the below-described Examples.

### Preparation of Tetramethylammonium Hypochlorite ((CH₃)₄NClO₃) or Tetramethylammonium Bromate ((CH₃)₄NBrO₃)

A saturated solution obtained by adding sodium chlorate (manufactured by FUJIFILM Wako Pure Chemical Corporation) or sodium bromate (manufactured by FUJIFILM Wako Pure Chemical Corporation) to ion-exchanged water was stored in a refrigerator for 24 hours, and the resulting precipitated sodium bromate was recovered by filtration. The thus recovered sodium bromate was dissolved in ultrapure water and analyzed using an ion chromatography analyzer. By analyzing CO₃⁻, SO₄⁻, and Br⁻ in the resulting diluted solution, it was confirmed that Na₂CO₃, Na₂SO₄, and NaBr contained as impurities were reduced. The concentrations of CO₃⁻, SO₄⁻, and Br⁻ were verified to be 500 ppb or less by repeating the above-described purification operation, whereby purified sodium chlorate or sodium bromate was obtained.

Next, 200 mL of a strongly acidic ion exchange resin (AMBERLITE IR-120BNa, manufactured by Organo Corporation) was added to a glass column having an inner diameter of about 45 mm (BIO COLUMN CF-50TK, manufactured by AsOne Corporation). Subsequently, 1 L of IN hydrochloric acid (manufactured by FUJIFILM Wako Pure Chemical Corporation, for volumetric analysis) was passed through the thus obtained ion exchange resin column to exchange the ion exchange resin into a hydrogen form, and 1 L of ultrapure water was passed through the column to wash the ion exchange resin. Further, 2 L of a 2.38% tetramethylammonium hydroxide solution was passed through the ion exchange resin thus exchanged into a hydrogen form so as to ion-exchange the resin from the hydrogen form into a tetramethylammonium form. Thereafter, 1 L of ultrapure water was passed through the column to wash the ion exchange resin.

After putting 6.4 g of the above-purified sodium chlorate or sodium bromate into a fluororesin container, 93.6 g of ultrapure water was added thereto to prepare a 6.4%-by-mass aqueous solution of sodium chlorate or sodium bromate. The thus obtained aqueous solution of sodium chlorate or sodium bromate was applied to the ion exchange resin exchanged into a tetramethylammonium form. For the thus recovered tetramethylammonium chlorate or tetramethylammonium bromate, the Na concentration was analyzed by high-frequency inductively-coupled plasma emission spectrometry (iCAP6500DuO, manufactured by Thermo Fisher Scientific Inc.) to confirm that the ion exchange was sufficiently carried out. When the ion exchange was not sufficient, the above-described operations were repeated to obtain a 10%-by-mass tetramethylammonium chlorate or tetramethylammonium bromate solution having a Na concentration of 500 ppb or less. The thus obtained solution was heat-treated to obtain a tetramethylammonium chlorate powder or a tetramethylammonium bromate powder. This tetramethylammonium chlorate powder or tetramethylammonium bromate powder was added to a treatment liquid to generate chlorate ions or bromate ions.

### (Other Reagents)

The reagents used in Examples and Comparative Examples are as follows.

Tetramethylammonium bromide ((CH₃)₄NBr): manufactured by Tokyo Chemical Industry Co., Ltd.

15%-by-weight HCl: manufactured by Kanto Chemical Co., Inc. (prepared by diluting 35%-by-weight HCl with ultrapure water)

1-mol/L tetramethylammonium hydroxide (TMAH): manufactured by Tokuyama Corporation (prepared by diluting 25%-by-weight TMAH with ultrapure water)

### (Method of Measuring of Hypobromite Ion Concentration and Hypochlorite Ion Concentration)

A UV-visible spectrophotometer (UV-2600, manufactured by Shimadzu Corporation) was used for the measurement of the hypobromite ion concentration and the hypochlorite ion concentration. Calibration curves prepared using aqueous solutions each having a known concentration of hypobromite ion or hypochlorite ion were used to determine the hypobromite ion concentration and the hypochlorite ion concentration in a produced treatment liquid.

### (Method of Measuring Anion Species Concentration)

The anion species concentration in a semiconductor wafer treatment liquid was analyzed using an ion chromatography analyzer (DIONEX INTEGRION HPLC, manufactured by Thermo Fisher Scientific Inc.). KOH was used as an eluent and passed through a column at a flow rate of 1.2 mL/min. As the column, an anion analysis column for hydroxide-based eluents (AS15, manufactured by Thermo Fisher Scientific Inc.) was used, and the column temperature was set at 30° C. After removing the background noise using a suppressor, the amount of anion species in the treatment liquid was quantified using an electroconductivity detector.

### (Method of Measuring pH)

For 10 mL of each treatment liquid prepared in Examples and Comparative Examples, the pH was measured using a tabletop pH meter (LAQUA F-73, manufactured by Horiba, Ltd.). The pH measurement was carried out after each treatment liquid was prepared and stabilized at 25° C.

### (Preparation of Semiconductor Wafers for Evaluation of Metal Etching Performance)

A ruthenium film, molybdenum film, tungsten film, and chromium film that were used in Examples and Comparative Examples were formed as follows. The ruthenium film, molybdenum film, and chromium film were obtained by forming an oxide film on a silicon wafer using a batch-type thermal oxidation furnace, and subsequently depositing 100 Å of ruthenium, 500 Å molybdenum, and 500 Å of chromium, respectively, on the oxide film by a sputtering method. Similarly, the tungsten film was obtained by forming a thermal oxide film and depositing thereon 500 Å of tungsten by a CVD method. The sheet resistance was measured using a four-probe resistivity meter (LORESTA GP, manufactured by Mitsubishi Chemical Analytech Co., Ltd.) and converted into film thickness, and this value was defined as the metal film thickness before etching treatment.

### (Evaluation of Metal Etching Performance)

Each treatment liquid of Examples in an amount of 60 mL was prepared in a fluororesin container provided with a lid (94.0-mL PFA container, manufactured by As One Corporation). Each 10 mm×20 mm semiconductor wafer piece to be evaluated was immersed in the treatment liquid for 1 minute at the treatment temperature (30° C. to 50° C.) shown in Table 1, and the amount of change in the film thickness before and after the treatment was divided by the immersion time to calculate the etching rate.

### (Evaluation of Etching Rate Stability)

The etching rate stability was evaluated as follows. The etching rate of each produced treatment liquid was evaluated at 10-hour intervals in accordance with the above-described “Evaluation of Metal Etching Performance”. A period in which an increase or decrease in the thus determined etching rate was within ±20% with respect to the etching rate immediately after the production of the treatment liquid was defined as “etching rate stability time” and classified based on the following criteria. The length of the etching rate stability time is in descending order from A to D, and the evaluations A to C are all acceptable levels while the evaluation D is an unacceptable level.

A: The etching rate stability time was 100 hours or longer, and the treatment liquid can be used particularly preferably.

B: The etching rate stability time was 50 hours or longer, and the treatment liquid can be used more preferably.

C: The etching rate stability time was 10 hours or longer, and the treatment liquid can be used preferably.

D: The etching rate stability time was shorter than 10 hours.

### (Evaluation of Etched Surface (Evaluation of Flatness))

The metal surface was observed before and after etching under a field-emission scanning electron microscope (JSM-7800F Prime, manufactured by JEOL Ltd.) to check the presence or absence of surface roughness, and the surface roughness was evaluated based on the following criteria. The amount of surface roughness increases (flatness is less maintained) in the order from A to D, and the evaluations A to C are all acceptable levels while the evaluation D is an unacceptable level.

A: No surface roughness was observed.

B: A slight surface roughness was observed.

C: Roughness was observed over the entire surface, but was shallow.

D: Deep roughness was observed over the entire surface.

### (Method of Quantifying Metals in Halogen Oxyacid)

The metal concentration in a halogen oxyacid was measured by high-resolution inductively-coupled plasma mass spectrometry. To a 25-mL polyfluoroalkyl ether (PFA) volumetric flask (PFA volumetric flask, manufactured by AsOne Corporation), ultrapure water and 1.25 mL of high-purity nitric acid (ULTRAPURE-100 nitric acid, manufactured by Kanto Chemical Co., Inc.,) were added. Subsequently, 0.25 mL of a halogen oxyacid was collected using a pipette (PIPETMAN P1000, manufactured by As One Corporation) with a fluororesin pipette tip (manufactured by AsOne Corporation), and added to the PFA volumetric flask, followed by stirring. Then, the resultant was diluted with ultrapure water in the volumetric flask to prepare a 10 to 100-fold diluted measurement sample in accordance with the halogen oxyacid concentration. Thereafter, metals were quantified by a calibration curve method using a high-resolution inductively-coupled plasma mass spectrometer (ELEMENT 2, manufactured by Thermo Fisher Scientific Inc.). Further, in order to verify the change in sensitivity caused by the matrix, a measurement solution in which impurities were added at a concentration of 2 ppb was measured as well. As for the measurement conditions, the RF output was 1,500 W, and the argon gas flow rate was 15 L/min for plasma gas, 1.0 L/min for auxiliary gas, and 0.7 L/min for nebulizer gas.

### Example 1

### (Method of Producing Treatment Liquid Containing Tetramethylammonium Hypobromite)

### (Step of Preparing Solution Containing Bromine Salt and Organic Alkali)

Tetramethylammonium bromide (14.6 g; 0.095 mol) and tetramethylammonium hydroxide (18.2 g; 0.190 mol) were put into a 2-L three-necked glass flask (manufactured by Cosmos Bead Co., Ltd.), and ultrapure water was added thereto to prepare 1 L of a solution which had a pH of 13.3 and contained a bromine salt and an organic alkali.

(Step of Allowing Solution Containing Bromine Salt and Organic Alkali to React with Halogen)

Subsequently, a stirrer bar (30 mm in total length×8 mm in diameter, manufactured by As One Corporation) was put into the three-necked flask, and a thermometer protection tube (bottom-closed type, manufactured by Cosmos Bead Co., Ltd.) and a thermometer were inserted through one of the openings. Through other opening, a tip of a PFA tube (F8011-02, manufactured by Flon Industry Co., Ltd.), which was connected to a chlorine gas cylinder and a nitrogen gas cylinder in such a manner to allow optionally switching between chlorine gas and nitrogen gas, was immersed to the bottom of the solution, and the remaining opening was connected to a gas washing bottle (Model Number 2450/500, manufactured by AsOne Corporation) filled with a 5%-by-mass aqueous sodium hydrogen solution. Nitrogen gas was supplied through the PFA tube at 200 sccm for 20 minutes to purge carbon dioxide from a gas-phase portion. Thereafter, a magnetic stirrer (C-MAG HS10, manufactured by AsOne Corporation) was placed on the bottom of the three-necked flask, and chlorine gas (manufactured by Fujiox Co., Ltd. specification purity: 99.4%) was supplied at 200 sccm for 10.6 minutes (total chlorine supply: 0.095 mol) with the magnetic stirrer being rotated at 300 rpm and the periphery of the three-necked flask being cooled with ice water. The solution temperature during reaction was 15° C.

By the above-described reaction, a halogen oxyacid containing a 0.095-mol/L tetramethylammonium hypobromite solution (further containing 0.19 mol/L of tetramethylammonium chloride and 0.01 mol/L of tetramethylammonium hydroxide) was obtained. The thus obtained halogen oxyacid was diluted to 1/100 by mixing with ultrapure water, 15% A-by-weight HCl, and 1-mol/L tetramethylammonium hydroxide (TMAH), whereby 100 mL of a treatment liquid having the formulation shown in Table 1 was obtained.

### (Evaluation of Treatment Liquid)

For the thus obtained treatment liquid, the hypohalite ion concentration, the anion species concentration, and the pH were measured by the above-described methods. Further, using the thus obtained treatment liquid, the metal etching performance, the etching rate stability, and the etched surface were evaluated by the above-described methods. The results thereof are shown in Tables 2 and 3.

### Examples 2 to 12

Halogen oxyacid-containing treatment liquids shown in Table 1 were obtained in the same manner as in “Method of Producing Treatment Liquid Containing Tetramethylammonium Hypobromite” described in Example 1, except that the concentrations of the bromine salt and the organic alkali and the supply amount of chlorine gas were adjusted as appropriate. The thus obtained treatment liquids were evaluated in the same manner as in Example 1. The results thereof are shown in Tables 2 and 3.

### Examples 13 to 16

Halogen oxyacids were obtained in the same manner as in “Method of Producing Treatment Liquid Containing Tetramethylammonium Hypobromite” described in Example 1, except that the concentrations of the bromine salt and the organic alkali and the supply amount of chlorine gas were adjusted as appropriate. It is noted here that, in Example 15, the flask was heated and chlorine gas was supplied at a solution temperature of 45° C. for generation of bromite ions. The thus obtained halogen oxyacids were each diluted to 1/100 by mixing with tetramethylammonium bromate, ultrapure water, 15%-by-weight HCl, and 1-mol/L TMAH, whereby treatment liquids having the respective formulations shown in Table 1 were obtained each in an amount of 100 mL. The thus obtained treatment liquids were evaluated in the same manner as in Example 1. The results thereof are shown in Tables 2 and 3.

### Example 17

### (Production of Treatment Liquid Containing Tetramethylammonium Hypobromite and Tetramethylammonium Hypochlorite)

Tetramethylammonium hydroxide (109.4 g) was put into a 2-L three-necked glass flask, and ultrapure water was added thereto to prepare 0.99 L of a solution which had a pH of 14.1 and contained a bromine salt and an organic alkali. This solution was allowed to react in the same manner as in “Step of Allowing Solution Containing Bromine Salt and Organic Alkali to React with Halogen” described in Example 1, except that the duration of supplying chlorine gas to the solution containing the bromine salt and the organic alkali was changed to 66.6 minutes (total chlorine supply: 0.595 mol). The solution temperature during reaction was 15° C.

By the above-described reaction, a 0.595-mol/L tetramethylammonium hypochlorite solution (further containing 0.595 mol/L of tetramethylammonium chloride and 0.01 mol/L of tetramethylammonium hydroxide) was obtained. At this point, the solution temperature was 15° C. To the thus obtained tetramethylammonium hypochlorite solution, 14.6 g of tetramethylammonium bromide was added, and 0.095 mol/L of hypobromite ions was generated by oxidation of bromide ions with hypochlorite ions. Further, the resultant was diluted to 1/100 by mixing with ultrapure water, 15%-by-weight HCl. and 1-mol/L TMAH, whereby 100 mL of a treatment liquid having the formulation shown in Table 1 was obtained. The thus obtained treatment liquid was evaluated in the same manner as in Example 1. The results thereof are shown in Tables 2 and 3.

### Example 18

Tetramethylammonium bromide (14.6 g; 0.095 mol) and tetramethylammonium hydroxide (109.4 g; 1.20 mol) were put into a 2-L three-necked glass flask, and ultrapure water was added thereto to prepare 0.99 L of a solution which had a pH of 14.1 and contained a bromine salt and an organic alkali. This solution was allowed to react in the same manner as in “Step of Allowing Solution Containing Bromine Salt and Organic Alkali to React with Halogen” described in Example 1, except that the duration of supplying chlorine gas to the solution containing the bromine salt and the organic alkali was changed to 66.6 minutes (total chlorine supply: 0.595 mol). The solution temperature during reaction was 15° C.

By the above-described reaction, 0.095-mol/L tetramethyl hypobromite and 0.595-mol/L tetramethylammonium hypochlorite (further containing 0.595 mol/L of tetramethylammonium chloride and 0.01 mol/L of tetramethylammonium hydroxide) were produced, and a halogen oxyacid-containing solution was thereby obtained. At this point, the solution temperature was 15° C. The thus obtained halogen oxyacid-containing solution was diluted to 1/100 by mixing with tetramethylammonium bromate, ultrapure water, 15%-by-weight HCl, and 1-mol/L TMAH, whereby 100 mL of a treatment liquid having the formulation shown in Table 1 was obtained. The thus obtained treatment liquid was evaluated in the same manner as in Example 1. The results thereof are shown in Tables 2 and 3.

### Comparative Examples 1 to 6

Treatment liquids shown in Table 1 were obtained by the same method as in Example 1. It is noted here that, in Comparative Example 1, chlorine was supplied to an organic alkali containing no bromine salt, and this organic alkali was allowed to react with chlorine. Further, in Comparative Example 4, a treatment liquid was obtained by dissolving a bromide into an organic alkali. The thus obtained treatment liquids were evaluated in the same manner as in Example 1. The results thereof are shown in Tables 2 and 3.

TABLE I

| | Treatment liquid | | | | | Treatment |
|---|---|---|---|---|---|---|
| | Hypobromite ion | Chloride ion | Anion species | Oxidizing agent | | temperature |
| | (mmol/L) | (mmol/L) | (mmol/L) | (mmol/L) | pH | (° C.) |
| Example 1 | 0.95 | 1.9 | — | — | 12 | 30 |
| Example 2 | 0.5 | 1 | — | — | 12 | 30 |
| Example 3 | 0.1 | 0.2 | — | — | 12 | 30 |
| Example 4 | 0.01 | 0.02 | — | — | 11.5 | 40 |
| Example 5 | 0.001 | 0.002 | — | — | 11 | 50 |
| Example 6 | 0.5 | 1 | — | — | 10 | 30 |
| Example 7 | 0.5 | 1 | — | — | 11 | 30 |
| Example 8 | 0.5 | 1 | — | — | 13 | 30 |
| Example 9 | 0.5 | 1 | — | — | 12 | 50 |
| Example 10 | 0.9 | 1.8 | — | — | 14 | 80 |
| Example 11 | 0.0001 | 0.0002 | — | — | 11 | 60 |
| Example 12 | 0.0005 | 0.001 | — | — | 8 | 80 |
| Example 13 | 0.5 | 1 | chlorate ion (30) | — | 12 | 30 |
| Example 14 | 0.95 | 1.9 | bromate ion (30) | — | 12 | 30 |
| Example 15 | 0.5 | 1 | bromate ion (20), | — | 12 | 30 |
| | | | bromite ion (10) | | | |
| Example 16 | 0.5 | 1 | bromate ion (30), | — | 12 | 30 |
| | | | bromide ion (100) | | | |
| Example 17 | 0.95 | 1.9 | — | hypochlorite ion (5) | 12 | 30 |
| Example 18 | 0.95 | 1.9 | bromate ion (30) | hypochlorite ion (5) | 12 | 30 |
| Comparative | — | — | — | hypochlorite ion (0.5) | 12 | 30 |
| Example 1 | | | | | | |
| Comparative | 0.00001 | 0.00002 | — | — | 11 | 60 |
| Example 2 | | | | | | |
| Comparative | 5 | 10 | — | — | 12 | 30 |
| Example 3 | | | | | | |
| Comparative | — | — | bromide ion (100) | — | 12 | 30 |
| Example 4 | | | | | | |
| Comparative | 1.3 | 2.6 | — | — | 12 | 60 |
| Example 5 | | | | | | |
| Comparative | 29 | 58 | — | — | 11 | 50 |
| Example 6 | | | | | | |

TABLE 2

| | Ruthenium | | | Tungsten | | |
|---|---|---|---|---|---|---|
| | Etching | Etching | | Etching | Etching | |
| | rate | rate | | rate | rate | |
| | (Å/min) | stability | Flatness | (Å/min) | stability | Flatness |
| Example 1 | 38 | A | A | 145 | A | A |
| Example 2 | 23 | A | A | 100 | A | A |
| Example 3 | 14 | A | B | 75 | A | B |
| Example 4 | 12 | A | B | 58 | A | B |
| Example 5 | 10 | B | B | 52 | B | B |
| Example 6 | 58 | C | B | 264 | C | B |
| Example 7 | 45 | B | A | 183 | B | A |
| Example 8 | 18 | A | A | 75 | A | A |
| Example 9 | 68 | A | C | 298 | A | C |
| Example 10 | 10 | C | C | 52 | C | C |
| Example 11 | 10 | B | B | 57 | B | B |
| Example 12 | 15 | C | C | 78 | C | C |
| Example 13 | 17 | A | A | 84 | A | A |
| Example 14 | 32 | A | A | 145 | A | A |
| Example 15 | 18 | A | A | 87 | A | A |
| Example 16 | 15 | A | A | 65 | A | A |
| Example 17 | 50 | A | A | 241 | A | A |
| Example 18 | 45 | A | A | 189 | A | A |
| Comparative | 1 | A | D | 15 | A | D |
| Example 1 | | | | | | |
| Comparative | 0 | No data | No data | 0 | No data | No data |
| Example 2 | | | | | | |
| Comparative | 80 | A | D | 320 | A | D |
| Example 3 | | | | | | |
| Comparative | 0 | No data | No data | 0 | No data | No data |
| Example 4 | | | | | | |
| Comparative | >100 | A | D | >500 | A | D |
| Example 5 | | | | | | |
| Comparative | >100 | C | D | >500 | C | D |
| Example 6 | | | | | | |

TABLE 3

| | Molybdenum | | | Chromium | | |
|---|---|---|---|---|---|---|
| | Etching | Etching | | Etching | Etching | |
| | rate | rate | | rate | rate | |
| | (Å/min) | stability | Flatness | (Å/min) | stability | Flatness |
| Example 1 | 112 | A | A | 99 | A | A |
| Example 2 | 69 | A | A | 68 | A | A |
| Example 3 | 62 | A | B | 61 | A | B |
| Example 4 | 54 | A | B | 55 | A | B |
| Example 5 | 51 | B | B | 52 | B | B |
| Example 6 | 130 | C | B | 98 | C | B |
| Example 7 | 86 | B | A | 72 | B | A |
| Example 8 | 63 | A | A | 54 | A | A |
| Example 9 | 139 | A | C | 103 | A | C |
| Example 10 | 56 | C | C | 55 | C | C |
| Example 11 | 54 | B | B | 56 | B | B |
| Example 12 | 74 | C | C | 75 | C | C |
| Example 13 | 62 | A | A | 54 | A | A |
| Example 14 | 72 | A | A | 59 | A | A |
| Example 15 | 67 | A | A | 55 | A | A |
| Example 16 | 56 | A | A | 53 | A | A |
| Example 17 | 117 | A | A | 100 | A | A |
| Example 18 | 87 | A | A | 70 | A | A |
| Comparative | 4 | A | D | 3 | A | D |
| Example 1 | | | | | | |
| Comparative | 0 | No data | No data | 0 | No data | No data |
| Example 2 | | | | | | |
| Comparative | 151 | A | D | 105 | A | D |
| Example 3 | | | | | | |
| Comparative | 0 | No data | No data | 0 | No data | No data |
| Example 4 | | | | | | |
| Comparative | >500 | A | D | >500 | A | D |
| Example 5 | | | | | | |
| Comparative | >500 | C | D | >500 | C | D |
| Example 6 | | | | | | |

In Table 1, “-” indicates the absence of corresponding ion or oxidizing agent in the treatment liquid (the same also applies to Tables 4, 6 and 8). Further, “No data” in Tables 2 and 3 indicates that, since etching did not proceed with the treatment liquid, the etching rate stability and the flatness could not be evaluated, and no data was thus obtained. As shown in Tables 2 and 3, when the treatment liquids of Comparative Examples 1 to 6 were used, an effect of satisfying all of the etching rate, the etching rate stability, and the flatness was not obtained. On the other hand, the treatment liquids according to the present embodiment, which are shown in Examples 1 to 16, yielded results that a sufficient etching rate and a sufficient etching rate stability were exerted and the etched surface had satisfactory flatness.

### Examples 19 to 27 and Comparative Examples 7 and 8

### (Production of RuO₄ Gas Generation Inhibitors)

In a 100-mL fluororesin container, the 0.095-mol/L aqueous tetramethylammonium hypochlorite solution prepared in accordance with the method described in Example 1 and tetramethylammonium bromate powder were mixed with tetrapropylammonium chloride (manufactured by Tokyo Chemical Industry Co., Ltd.), hexyltrimethylammonium chloride (manufactured by Tokyo Chemical Industry Co., Ltd.), n-octyltrimethylammonium chloride (manufactured by Tokyo Chemical Industry Co., Ltd.), or hexamethonium chloride dihydrate (manufactured by Tokyo Chemical Industry Co., Ltd.), along with ultrapure water, 15%-by-weight HCl, and 1-mol/L NaOH to obtain RuO₄ gas generation inhibitors having the respective formulations shown in Tables 4 to 7, each in an amount of 30 mL. It is noted here that, in Example 25, the flask was heated and chlorine gas was supplied at a solution temperature of 45° C. for generation of bromite ions. For each of the thus obtained RuO₄ gas generation inhibitors, the hypobromite ion concentration, the hypochlorite ion concentration, the anion species concentration, and the pH were measured by the above-described methods.

### (Production of Liquid for Treating Ruthenium)

In a 100-mL fluororesin container, sodium hypochlorite (NaClO; manufactured by Wako Pure Chemical Industries, Ltd.) and ultrapure water were added, and the pH of the resultant was adjusted as shown in Tables 4 to 7 using a 15%-by-mass aqueous HCl solution or a 1.0 mol/L aqueous NaOH solution, whereby 30 mL of a liquid for treating ruthenium was obtained.

### (Quantitative Analysis of RuO₄ Gas)

First, each RuO₄ gas generation inhibitor and liquid for treating ruthenium, which were prepared in the above-described respective procedures, were mixed to obtain 60 mL of a mixture. Next, 10 ml of this mixture having the respective formulation shown in Examples 19 to 27 and Comparative Example 7 and 8 was added to a 85-ml hermetically-sealed glass container, and a silicon wafer having a sputtered ruthenium film (5 mm×5 mm. Ru film thickness=20 nm; 5.4×10⁻⁸ mol in terms of Ru amount) was immersed therein at 25° C. for 15 minutes. The Ru film thickness was measured by XRF to confirm that all of Ru on the wafer was dissolved.

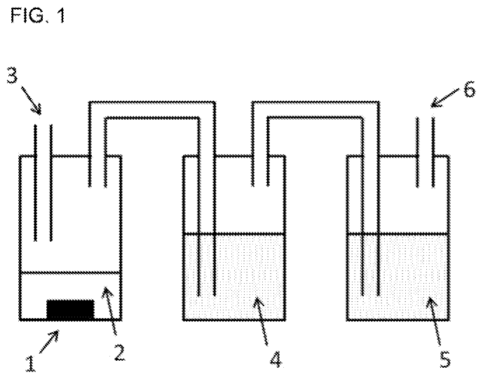

Subsequently, nitrogen gas was allowed to flow in the hermetically-sealed container at a rate of 300 ml/min for 15 minutes to cause RuO₄ gas, which was generated during the immersion of the silicon wafer having a ruthenium film, to be sequentially absorbed by a gas trapping liquid 4 and a gas trapping liquid 5 as illustrated in the schematic drawing of FIG. 1. As the gas trapping liquids 4 and 5, an aqueous tetramethylammonium hydroxide (TMAH) solution having a concentration of 1 mol/L was used. Subsequently, the gas trapping liquids 4 and 5 were each fractionated in an amount of 10 ml, and 20 ml of hydrochloric acid and ultrapure water were added thereto to a total amount of 100 ml, after which the resultants were left to stand for 24 hours to obtain measurement liquids. These measurement liquids were analyzed by ICP-MS (ICP-MS7900 manufactured by Agilent Technologies, Inc., Ru detection m/z=101) to quantify Ru. Since Ru was not detected in the gas trapping liquid 5 the amount of Ru absorbed by the gas trapping liquid 4 was taken as the RuO₄ gas quantitative value. It is noted here that the Ru amounts shown in Tables 5 and 7 are each a value obtained by dividing the weight of Ru contained in the RuO₄ gas-absorbed liquid by the area of the wafer having a Ru film.

TABLE 4

| | RuO₄ gas generation inhibitor | | | | |
|---|---|---|---|---|---|
| | Onium salt | | | | |
| | | Bromine- | Oxidizing | | |
| | Onium ion | containing | agent | | |
| | (mmol/L) | ion (mmol/L) | (mol/L) | Solvent | pH |
| Example 19 | tetrapropyl- | hypobromite | — | water | 12 |
| | ammonium ion | ion (0.95) | | | |
| | (0.95) | | | | |
| Example 20 | tetrapropyl- | hypobromite | — | water | 12 |
| | ammonium ion (0.5) | ion (0.5) | | | |
| Example 21 | hexyltrimethyl- | hypobromite | — | water | 12 |
| | ammonium ion (0.5) | ion (0.5) | | | |
| Example 22 | n -octyltrimethyl- | hypobromite | — | water | 12 |
| | ammonium ion (0.1) | ion (0.1) | | | |
| Example 23 | hexamethonium | hypobromite | — | water | 12 |
| | ion (0.5) | ion (0.5) | | | |
| Example 24 | tetrapropyl- | hypobromite | — | water | 12 |
| | ammonium ion | ion (0.5). | | | |
| | (0.95) | bromide ion | | | |
| | | (0.45) | | | |
| Example 25 | tetrapropyl- | hypobromite | — | water | 12 |
| | ammonium ion | ion (0.5). | | | |
| | (0.95) | bromite ion | | | |
| | | (0.05). | | | |
| | | bromide ion | | | |
| | | (0.4) | | | |
| Example 26 | tetrapropyl- | hypobromite | hypo- | water | 12 |
| | ammonium ion | ion (0.95) | chlorite | | |
| | (0.95) | | ion (0.005) | | |
| Example 27 | tetrapropyl- | hypobromite | ortho- | water | 12 |
| | ammonium ion | ion (0.95) | periodate | | |
| | (0.95) | | ion (0.005) | | |

TABLE 5

| | | | | Amount |
|---|---|---|---|---|
| | | | pH | of Ru in |
| | Liquid for treating ruthenium | | after | RuO₄ gas |
| | Oxidizing agent (mol/L) | pH | mixing | (ng/cm2) |
| Example 19 | 0.28 mol/L aqueous NaClO solution | 12 | 12 | 3.1 |
| Example 20 | 0.28 mol/L aqueous NaClO solution | 12 | 12 | 5.4 |
| Example 21 | 0.28 mol/L aqueous NaClO solution | 12 | 12 | 1.7 |
| Example 22 | 0.28 mol/L aqueous NaClO solution | 12 | 12 | 0.9 |
| Example 23 | 0.28 mol/L aqueous NaClO solution | 12 | 12 | 4.5 |
| Example 24 | 0.28 mol/L aqueous NaClO solution | 12 | 12 | 2.9 |
| Example 25 | 0.28 mol/L aqueous NaClO solution | 12 | 12 | 3 |
| Example 26 | 0.28 mol/L aqueous NaClO solution | 12 | 12 | 3.1 |
| Example 27 | 0.28 mol/L aqueous NaClO solution | 12 | 12 | 2.8 |

TABLE 6

| | RuO₄ gas generation inhibitor | | | | |
|---|---|---|---|---|---|
| | Cation | Anion | Oxidizing | | |
| | (mmol/L) | (mmol/L) | agent (mol/L) | Solvent | pH |
| Comparative | sodium ion | hypobromite | — | water | 12 |
| Example 7 | (0.95) | ion (0.95) | | | |
| Comparative | sodium ion | hypobromite | hypochlorite | water | 12 |
| Example 8 | (0.95) | ion (0.95) | ion (0.005) | | |

TABLE 7

| | | | | Amount of |
|---|---|---|---|---|
| | | | pH | Ru in |
| | Liquid for treating ruthenium | | after | RuO₄ gas |
| | Oxidizing agent (mol/L) | pH | mixing | (ng/cm2) |
| Comparative | 0.28 mol/L aqueous | 12 | 12 | 30 |
| Example 7 | NaClO solution | | | |
| Comparative | 0.28 mol/L aqueous | 12 | 12 | 31 |
| Example 8 | NaClO solution | | | |

From the results shown in Tables 4 to 7, it was found that generation of RuO₄ gas was inhibited by adding the RuO₄ gas generation inhibitor of the present invention to the respective liquids for treating ruthenium. This indicates that the RuO₄ gas generation inhibitor of the present invention can be preferably used for treating ruthenium.

Metals contained in the produced halogen oxyacids were quantified as follows. The metals contained in the halogen oxyacids produced in Examples 1, 14, 17 and 18 as well as Reference Examples 1 and 2 described below were measured by the above-described “Method of Quantifying Metals in Halogen Oxyacid”. The results of quantifying the metals contained in the produced halogen oxyacids are shown in Table 8.

### (Production of Halogen Oxyacids by Ion Exchange)

### <Pretreatment of Ion Exchange Resin: Preparation of Hydrogen-Form Ion Exchange Resin>

A sodium-form strongly acidic ion exchange resin (AMBERLITE IR-120BNa, manufactured by Organo Corporation) in an amount of 200 mL was added to a glass column having an inner diameter of about 45 mm (BIO COLUMN CF-50TK, manufactured by AsOne Corporation). Subsequently, 1 L of IN hydrochloric acid (manufactured by Wako Pure Chemical Industries, Ltd., for volumetric analysis) was passed through the thus obtained ion exchange resin column to exchange the ion exchange resin into a hydrogen form, and 1 L of ultrapure water was passed through the column to wash the ion exchange resin.

<Step (a)>

Further, 1 L of a 10% tetramethylammonium hydroxide solution was passed through 209 mL of the ion exchange resin thus exchanged into a hydrogen form so as to ion-exchange the resin from the hydrogen form into a tetramethylammonium form. Thereafter, 1 L of ultrapure water was passed through the column to wash the ion exchange resin.

<Step (b1)>

After putting 125 g of a 9% aqueous sodium hypobromite solution (manufactured by Kanto Chemical Co., Inc., cica-reagent grade) in a 2-L fluororesin container, 875 g of ultrapure water was added thereto to prepare a 1.1%-by-mass aqueous sodium hypobromite solution. This aqueous sodium hypobromite solution was passed through the ion exchange resin exchanged into a tetramethylammonium form in the step (a) to obtain an aqueous tetramethylammonium hypobromite solution. To the thus obtained halogen oxyacid, ultrapure water and a tetramethylammonium hydroxide solution were added to produce a treatment liquid containing 0.1 mmol/L of tetramethylammonium hypobromite (pH 12.0).

<Step (b2)>

After putting 15.6 g of sodium hypochlorite pentahydrate (manufactured by Wako Pure Chemical Industries, Ltd., reagent grade) in a 2-L fluororesin container, 984 g of ultrapure water was added thereto to prepare a 7.1%-by-mass aqueous sodium hypochlorite solution. This aqueous sodium hypochlorite solution was passed through the ion exchange resin exchanged into a tetramethylammonium form in the step (a) to obtain an aqueous tetramethylammonium hypochlorite solution. To the thus obtained halogen oxyacid, ultrapure water and a tetramethylammonium hydroxide solution were added to produce a treatment liquid containing 0.1 mmol/L of tetramethylammonium hypochlorite (pH 12.0).

### Reference Example 1

The treatment liquid containing 0.1 mmol/L of tetramethylammonium hypobromite (pH 12.0), which was produced in the above-described step (b1) of “Production of Halogen Oxyacids by Ion Exchange”, was mixed with an aqueous tetramethylammonium hydroxide solution (pH 12.0) to obtain a halogen oxyacid containing hypobromous acid as shown in Table 8.

### Reference Example 2

The treatment liquid containing 0.1 mmol/L of tetramethylammonium hypobromite (pH 12.0) and the treatment liquid containing 0.1 mmol/L of tetramethylammonium hypochlorite (pH 12.0), which were produced in the above-described steps (b1) and (b2) of “Production of Halogen Oxyacids by Ion Exchange”, respectively, were mixed with an aqueous tetramethylammonium hydroxide solution (pH 12.0) to obtain a halogen oxyacid containing hypobromous acid and hypochlorous acid as shown in Table 8.

TABLE 8

| | (A) bromine | (B) organic | (C) anion | | (E) halogen oxyacid | (F) metal content (ppb) | | |
|---|---|---|---|---|---|---|---|---|
| | salt | alkali | species | (D) halogen | (mmol/L) | Na | K | Al |
| Example 1 | tetramethylammonium | tetramethylammonium | — | chlorine | tetramethylammonium | <1 | <1 | <1 |
| | bromide | hydroxide | | | hypobromite (0.95) | | | |
| Example 14 | tetramethylammonium | tetramethylammonium | bromate ion | chlorine | tetramethylammonium | <1 | <1 | <1 |
| | bromide | hydroxide | | | hypobromite (0.95) | | | |
| Example 17 | tetramethylammonium | tetramethylammonium | — | chlorine | tetramethylammonium | <1 | <1 | <1 |
| | bromide | hydroxide | | | hypobromite (0.95) | | | |
| | | | | | tetramethylammonium | | | |
| | | | | | hypochlorite (5) | | | |
| Example 18 | tetramethylammonium | tetramethylammonium | bromate ion | chlorine | tetramethylammonium | <1 | <1 | <1 |
| | bromide | hydroxide | bromide ion | | hypobromite (0.95) | | | |
| | | | | | tetramethylammonium | | | |
| | | | | | hypochlorite (5) | | | |
| Reference | — | — | — | — | tetramethylammonium | 87 | 23 | 13 |
| Example 1 | | | | | hypobromite (0.95) | | | |
| Reference | — | — | — | — | tetramethylammonium | 547 | 129 | 67 |
| Example 2 | | | | | hypobromite (0.95) | | | |
| | | | | | tetramethylammonium | | | |
| | | | | | hypochlorite (5) | | | |

The hypohalous acid-containing treatment liquids obtained in Examples 1, 14, 17, 18, 26, and 27 had substantially the same Ru etching rate. On the other hand, while the amounts of metals (Na, K, and Al) contained in the treatment liquids of Examples 1, 14, 17, and 18 were less than 1 ppb, the amounts of these metals were much greater in Reference Examples 1 and 2.

From the above-described results, it was demonstrated that a halogen oxyacid produced by the method of producing a halogen oxyacid according to the third embodiment of the present invention not only is capable of etching ruthenium at a sufficient rate but also has an extremely low metal content.

### DESCRIPTION OF SYMBOLS

1: silicon wafer with Ru
2: treatment liquid
3: N₂ gas inlet
4: gas trapping liquid 1
5: gas trapping liquid 2
6: exhaust pipe

1. A semiconductor treatment liquid, comprising a hypobromite ion,
wherein the concentration of the hypobromite ion is 0.1 μmol/L or more and lower than 0.001 mol/L.

2. The semiconductor treatment liquid according to claim 1, wherein the semiconductor comprises a transition metal.

3. The semiconductor treatment liquid according to claim 1, further comprising at least one anion species selected from the group consisting of a chlorate ion, a chlorite ion, a chloride ion, a bromate ion, a bromite ion, and a bromide ion.

4. The semiconductor treatment liquid according to claim 1, wherein
the semiconductor treatment liquid further comprises an oxidizing agent, and
the oxidizing agent has a redox potential higher than that of a hypobromite ion/bromide ion system.

5. The semiconductor treatment liquid according to claim 4, wherein the oxidizing agent is at least one oxidizing agent selected from the group consisting of a hypochlorite ion, ozone, an orthoperiodate ion, and a metaperiodate ion.

6. The semiconductor treatment liquid according to claim 1, further comprising a tetraalkylammonium ion.

7. The semiconductor treatment liquid according to claim 1, having a pH of 8 or higher and 14 or lower.

8. A RuO₄ gas generation inhibitor, comprising an onium salt composed of an onium ion and a bromine-containing ion,
wherein the concentration of the bromine-containing ion in the RuO₄ gas generation inhibitor is 0.1 μmol/L or more and less than 0.001 mol/L.

9. The RuO₄ gas generation inhibitor according to claim 8, wherein the onium salt is a quaternary onium salt represented by the following Formula (1), or a tertiary onium salt represented by the following Formula (2): 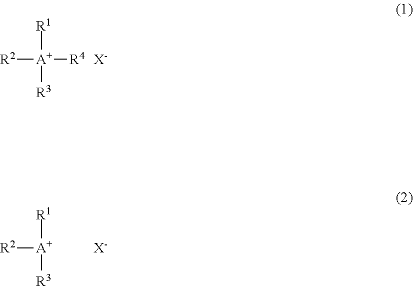
(in Formula (1), A represents nitrogen or phosphorus; R¹, R², R³, and R⁴ each independently represent an alkyl group having carbon number of 1 to 25, an allyl group, an aralkyl group containing an alkyl group having carbon number of 1 to 25, or an aryl group, provided that when R¹, R², R³, and R⁴ are alkyl groups, at least one of the alkyl groups of R¹, R², R³, and R⁴ has carbon number of 3 or more; and, in a ring of an aryl group in the aralkyl group and in a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom,
in Formula (2), A represents sulfur; R¹, R², and R³ each independently represent an alkyl group having carbon number of 1 to 25, an allyl group, an aralkyl group containing an alkyl group having carbon number of 1 to 25, or an aryl group, provided that when R¹, R², and R³ are alkyl groups, at least one of the alkyl groups of R¹, R², and R³ has carbon number of 3 or more; and, in a ring of an aryl group in the aralkyl group and a ring of the aryl group, at least one hydrogen atom is optionally substituted with a fluorine atom, a chlorine atom, an alkyl group having carbon number of 1 to 10, an alkenyl group having carbon number of 2 to 10, an alkoxy group having carbon number of 1 to 9, or an alkenyloxy group having carbon number of 2 to 9, in which groups at least one hydrogen atom is optionally substituted with a fluorine atom or a chlorine atom, and
X⁻ represents a bromine-containing ion).

10. The RuO₄ gas generation inhibitor according to claim 9, wherein the quaternary onium salt is a tetraalkylammonium salt.

11. The RuO₄ gas generation inhibitor according to claim 8, wherein the bromine-containing ion is a bromite ion, a bromate ion, a perbromate ion, a hypobromite ion, or a bromide ion.

12. The RuO₄ gas generation inhibitor according to claim 8, further comprising an oxidizing agent.

13. The RuO₄ gas generation inhibitor according to claim 12,
wherein
the oxidizing agent is a hypochlorite ion, and
the concentration of the hypochlorite ion is 500 ppb by mass to 20.0% by mass.

14. A method of producing a halogen oxyacid, the method comprising allowing a bromine salt, an organic alkali, and a halogen to react with each other to obtain the halogen oxyacid.

15. The method of producing a halogen oxyacid according to claim 14, wherein the organic alkali is an onium hydroxide.

16. The method of producing a halogen oxyacid according to claim 14, wherein the halogen is chlorine.

17. The method of producing a halogen oxyacid according to claim 14, wherein the concentration of the halogen oxyacid is 0.1 μmol/L or more and less than 0.001 mol/L.
